(19) United States
(12) Patent Application Publication
(10) Pub. No.: US 2026/0344026 A1
(43) Pub. Date: Oct. 29, 2026

(54) SOURCE/DRAIN CONTACT ISOLATION IN SEMICONDUCTOR DEVICES

(71) Applicant: Taiwan Semiconductor Manufacturing Company, Ltd., Hsinchu (TW)

(72) Inventors: Han-Yu LIN, Hsinchu County (TW); Fo-Ju LIN, Keelung City (TW); Wan-Ting KUNG, Taipei City (TW); Hsu-Kai CHANG, Hsinchu (TW); Min-Hsuan LU, Hsinchu City (TW); Sheng-Tsung WANG, Hsinchu (TW); An-Shen CHANG, Jubei City (TW); Pinyen LIN, Rochester, NY (US)

(73) Assignee: Taiwan Semiconductor Manufacturing Company, Ltd., Hsinchu (TW)

(21) Appl. No.: 19/193,411

(22) Filed: Apr. 29, 2025

(51) Int. Cl. H10D 84/83; H10D 30/00; H10D 30/01; H10D 30/43; H10D 62/10; H10D 62/13; H10D 84/01; H10P 50/00; H10P 52/40; H10P 76/40

(52) U.S. Cl. CPC H10D 84/832; H10D 30/014; H10D 30/019; H10D 30/43; H10D 30/502; H10D 62/121; H10D 62/151; H10D 84/0149; H10D 84/0151; H10D 84/83125; H10P 50/73; H10P 52/403; H10P 76/405; H10P 76/4085

(57) ABSTRACT

The present disclosure describes a method of reducing a width of isolation structures between adjacent source/drain contact structures of a field-effect-transistor (FET). The method includes patterning a stack of isolation layers by a patterned mask structure. A width of the patterned mask structure is shrunk by an ion-implantation and wet etching process. The stack of isolation layers is etched through the shrunken patterned mask structure to form isolation structures with a smaller width.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B and 1C illustrate cross-sectional views of a semiconductor device with nanostructured channel layers and source/drain contacts, in accordance with some embodiments.

FIG. 2 is a flow diagram of a method for fabricating a semiconductor device with nanostructured channel layers and source/drain contacts, in accordance with some embodiments.

FIGS. 3A, 3B, 3C, 4A, 4B, 4C, 4D, 4E, 4F, 5A, 5B, 5C, 5D, 5E, 5F, 6A, 6B, 6C, 6D, 6E, 6F, 7A, 7B, 7C, 7D, 7E, 7F, 8A, 8B, 8C, 9A, 9B, 9C, 10A, 10B, 10C, 11A, 11B, and 11C illustrate different cross-sectional views of a semiconductor device with nanostructured channel layers and source/drain contacts at various stages of its fabrication process, in accordance with some embodiments.

FIG. 8D illustrates a process for shrinking a patterned mask structure, in accordance with some embodiments.

FIG. 8E illustrates structural changes of a patterned mask structure during the shrinking process, in accordance with some embodiments.

FIG. 8F illustrates a distribution of implanted ions within a patterned mask structure, in accordance with some embodiments.

FIG. 8G illustrates a change in a width of a patterned mask structure with etching time during a wet etch process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not dictate a relationship between the embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15~20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The present disclosure is related to semiconductor devices and fabrication methods using a cut metal drain (CMD) process to reduce a spacing between adjacent source/drain (S/D) regions. A CMD process refers to a fabrication process, where inter-layer dielectric (ILD) layers and etch stop layers (ESLs) overlying the S/D regions are etched to form S/D contact openings. The openings are subsequently filled with a metal contact layer to form S/D contacts. A substrate with multiple gate-all-around field effect transistors (GAA FET) includes S/D regions formed on (a) either side of a gate structure of the GAA FET, and (b) S/D regions of adjacent GAA FETs formed on adjacent fin structures. S/D contacts of GAA FETs formed on adjacent fin structures can be separated by an isolation structure. A width of the this isolation structure is a critical dimension (CD) because a CD too large can affect current flow and a CD too small can lead to unintended coupling, causing cross-talk between adjacent S/D regions.

The CD of the isolation structure can suffer from uniformity degradation due to patterning and etching limitations. Masking material limitations, misalignment, and irregularities during patterning and etching can cause CD-related defects, which can lead to undesirable variations in device performance. For example, forming the isolation structure includes patterning hard mask layers. Hard mask layers formed of a soft material (e.g., a material with low young's modulus) can cause position and dimensional irregularities in the pattern transferred to the isolation layer. These patterning irregularities can cascade to a missing isolation structure or an isolation structure with a small width during subsequent processing operations.

In another example of a method to reduce the CD of the isolation structure, a directional etching of a hard mask layer can be used. However, the directional etching can lead to rounding of corners of the hard mask layer, leading to an isolation structure with a tapered profile. In another example, directional etching can be used to etch a dielectric layer formed on the S/D regions. The directional etching can however cause epitaxial loss, leading to damaged S/D regions. Additionally, it can lead to degradation of electrical properties of the S/D regions due to exposure to etch chemistries used during directional etching.

To address the aforementioned challenges, the present disclosure provides a method of reducing a width of the isolation structure between adjacent S/D contact structures. An isolation structure with a small width can provide a large metal fill volume for the S/D contact structures. The disclosed method can also form contact openings with substantially vertical sidewalls, which can also provide a large metal fill volume for the S/D contact structures. The disclosure provides an improved method of forming metal drain cuts and subsequently contact openings. The disclosed method provides accurate alignment, etching and overall pattern fidelity for the CMD process and for forming other structures with other critical dimensions.

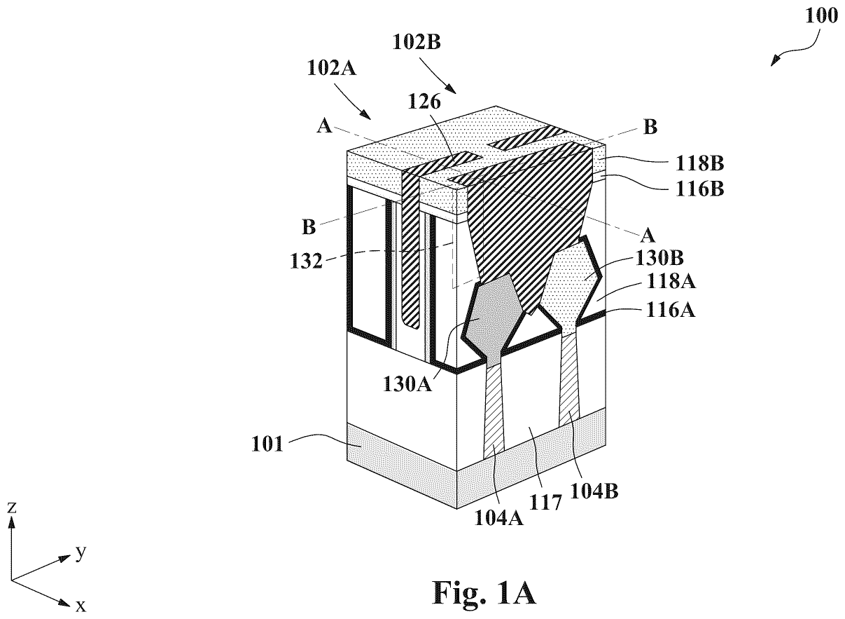

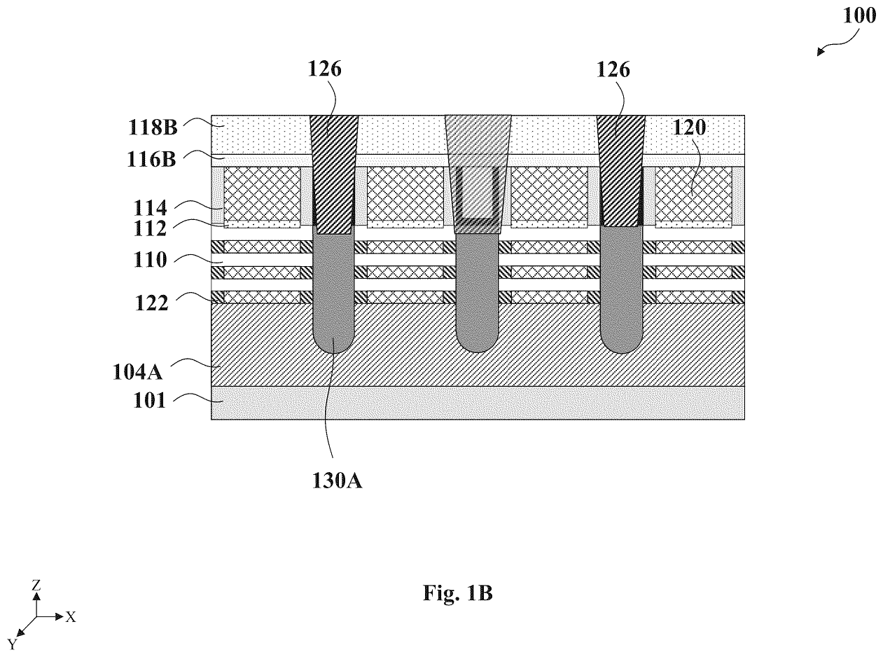

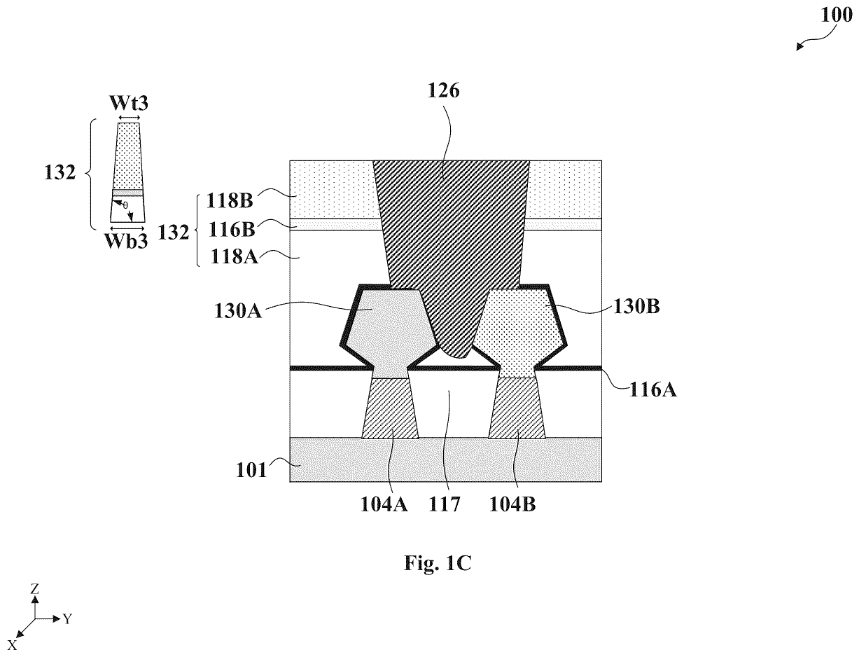

A semiconductor device 100 with FETs 102A and 102B is described with reference to FIGS. 1A-1C, according to some embodiments. In some embodiments, FETs 102A and 102B can represent GAA FETs. Though two FETs are discussed with reference to FIGS. 1A-1C, semiconductor device 100 can have any number of FETs. FETs 102A and 102B can be n-type, p-type, or a combination thereof. FIG. 1A illustrates an isometric view of semiconductor device 100, according to some embodiments. Semiconductor device 100 can have different cross-sectional views along lines A-A and B-B of FIG. 1A, according to some embodiments. Line A-A can extend along the x-axis and line B-B can extend along the y-axis. Isometric view of shown in FIG. 1A is a portion of semiconductor device 100 shown in FIG. 1B.

According to some embodiments, FIG. 1B illustrates a cross sectional view of FET 102A along line A-A of FIG. 1A, and shows a portion of semiconductor device 100. According to some embodiments, FIG. 1B illustrates a cross-sectional view of FETs 102A and 102B along line B-B of FIG. 1A. FIGS. 1B and 1C illustrate cross-sectional views of FETs 102A and 102B with additional elements that are not shown in FIG. 1A for simplicity. The discussion of FET 102A applies to FET 102B, unless mentioned otherwise. The discussion of elements in FIGS. 1A-1C with the same annotations applies to each other, unless mentioned otherwise.

Referring to FIGS. 1A-1C, semiconductor device 100 can be formed on substrate 101. Substrate 101 can be a semiconductor material, such as silicon, germanium (Ge), silicon germanium (SiGe), a silicon-on-insulator (SOI) structure, and a combination thereof. Further, substrate 101 can be doped with p-type dopants (e.g., boron, indium, aluminum, or gallium) or n-type dopants (e.g., phosphorus or arsenic).

Semiconductor device 100 can further include base structures 104A and 104B (also referred to as “sheet bases,” “fin bases,” or “protrusions”) which can extend along an x-axis. Base structures 104A and 104B can be separated by shallow trench isolation (STI) regions 117.

Referring to FIGS. 1B and 1C, in some embodiments, FETs 102A and 102B can further include (i) a stack of nanostructured channel layers (also referred to as “nanostructured layers 110” or “nanostructured channel regions 110”) disposed on base structure 104A, (ii) GAA structure 120 (also referred to as “gate structure 120”) disposed on and around nanostructured channel layers 110, (iii) S/D region 130A disposed on base structure 104A, adjacent to nanostructured channel layers 110, (iv) S/D region 130B disposed on base structure 104B, adjacent to nanostructured channel layers 110, (v) S/D contact structure 126 in contact with S/D regions 130A and 130B, (v) first ESL 116A to protect gate structure 120 and S/D regions 130A and 130B, (vi) first ILD layer 118A disposed on top of first ESL 116A, (vii) second ESL 116B disposed on first ILD layer 118A, (vi) second ILD layer 118B formed on second ESL 116B, and (vii) isolation structure 132 formed on either side of S/D contact structure 126. In some embodiments, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel layers 110 can be in the form of nanosheets, nanowires, nanorods, nanotubes, or other suitable nanostructured shapes.

According to some embodiments, isolation structure 132 can be formed of second dielectric later 118A, second ESL 116B, and first dielectric layer 118A. In some embodiments, isolation structure 132 can have a tapered shape with a top portion with width Wt3 and a bottom portion with width Wb3, where Wb3 can be greater than Wt1, as shown in the inset in FIG. 1C. The ratio of width Wt3 to Wb3 can, for example, be between about 0.9 and about 0.97. In some embodiments, isolation structure 132 can be tapered at an angle θ to the z-axis. Angle θ can be, for example, between about 84° and about 89°. For example, angle θ can be about 86.4°.

Referring to FIGS. 1B and 1C, S/D regions 130A and 130B can be grown on base structure 104A and 104B and can include epitaxially-grown semiconductor materials. In some embodiments, the epitaxially-grown semiconductor material can include the same material or a different material from the material of substrate 101. S/D regions 130A and 130B can be n- or p-type type. In some embodiments, the term “p-type” defines a structure, layer, and/or region doped with p-type dopants, such as boron, and the term “n-type” defines a structure, layer, and/or region doped with n-type dopants, such as phosphorus. In some embodiments, S/D regions 130A and 130B can include SiAs, SiC, SiCP, SiGe, SiGeB, GeB, SiGeSnB, a III-V semiconductor compound, any other suitable semiconductor material, or a combination thereof.

In some embodiments, S/D contact structure 126 on S/D regions 130A and 130B can include (i) a silicide layer (not shown), (ii) a liner (not shown), and (iii) a S/D metal contact layer disposed on silicide layer (not shown). In some embodiments, silicide layer can include nickel silicide (NiSi), tungsten silicide (WSi₂), titanium silicide (TiSi₂), cobalt silicide (CoSi₂), or other suitable metal silicides. In some embodiments, S/D metal contact layer can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), any other suitable conductive material, and a combination thereof. In some embodiments, liner can include a nitride material, such as titanium nitride (TiN) and tantalum nitride (TaN).

Gate structure 120 can be a multi-layered structure and can surround nanostructured channel layers 110, as shown in FIG. 1B. Gate structure 120 can be referred to as a “gate-all-around (GAA) structure.” A first portion of gate structure 120 disposed on the nanostructured channel layers 110 can be electrically isolated from adjacent S/D regions 130A and 130B by outer gate spacers 114. A second portion of gate structure 120 surrounding nanostructured channel layers 110 can be electrically isolated from adjacent S/D regions 130A and 130B by inner gate spacers 122. Inner gate spacers 122 and outer gate spacers 114 can include an insulating material, such as SiO₂, SiN, SiCN, SiOCN, and any other suitable insulating material.

Gate structure 120 can include (i) an interfacial oxide layer (IL) 112, (ii) a high-k (HK) gate dielectric layer, (iii) a work function metal (WFM) layer, and (iv) a gate metal fill layer. FIG. 1B shows that the layers of GAA structure 120 are wrapped around nanostructured channel layers 110.

IL layers 112 can be disposed on nanostructured channel layers 110. In some embodiments, IL layers 112 can include SiO₂, silicon germanium oxide (SiGeOₓ), germanium oxide (GeOₓ), or other suitable oxide materials. HK gate dielectric layers 130 can be disposed on IL layers 112 and can include (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. The term “high-k” refers to a high dielectric constant. In the field of semiconductor device structures and manufacturing processes, high-k can refer to a dielectric constant that is greater than the dielectric constant of SiO₂ (e.g., greater than 3.9).

WFM layer can be n-or p-type for n-or p-type FET 102A, respectively. In some embodiments, n-type WFM layer can include a metallic material with a work function value closer to a conduction band energy than a valence band energy of a material of nanostructured channel layers 110. For example, n-type WFM layer can include an Al-based or Al-doped metallic material with a work function value less than about 4.5 eV (e.g., about 3.5 eV to about 4.4 eV), which can be closer to the conduction band energy (e.g., 4.1 eV for Si or 3.8 eV for SiGe) than the valence band energy (e.g., 5.2 eV for Si or 4.8 eV for SiGe) of Si-based or SiGe-based NHC layers 124. In some embodiments, n-type WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based materials, or a combination thereof.

In some embodiments, p-type WFM layer can include a metallic material with a work function value closer to a valence band-edge energy than a conduction band-edge energy of a material of nanostructured channel layers 110. For example, p-type WFM layer can include a substantially Al-free (e.g., with no Al) metallic material with a work function value equal to or greater than 4.5 eV (e.g., about 4.5 eV to about 5.5 eV), which can be closer to the valence band-edge energy (e.g., 5.2 eV for Si or 4.8 eV for SiGe) than the conduction band-edge energy (e.g., 4.1 eV for Si or 3.8 eV for SiGe) of Si-based or SiGe-based nanostructured channel layers 110. In some embodiments, p-type WFM layer can include substantially Al-free (e.g., with no Al): (i) Ti-based nitrides or alloys, such as TiN, TiSiN, titanium gold (Ti—Au) alloy, titanium copper (Ti—Cu) alloy, titanium chromium (Ti—Cr) alloy, titanium cobalt (Ti—Co) alloy, titanium molybdenum (Ti—Mo) alloy, and titanium nickel (Ti—Ni) alloy; (ii) Ta-based nitrides or alloys, such as TaN, TaSiN, Ta—Au alloy, Ta—Cu alloy, Ta—W alloy, tantalum platinum (Ta—Pt) alloy, Ta—Mo alloy, Ta—Ti alloy, and Ta—Ni alloy; (iv) metal nitrides, such as molybdenum nitride (MoN) and tungsten nitride (WN); (iii) other suitable Al-free metallic materials; (iv) and combinations thereof. In some embodiments, WFM layer can include a thickness ranging from about 1 nm to about 4 nm.

In some embodiments, gate metal fill layer can include a suitable conductive material, such as tungsten (W), titanium (Ti), silver (Ag), ruthenium (Ru), molybdenum (Mo), copper (Cu), cobalt (Co), aluminum (Al), iridium (Ir), nickel (Ni), any other suitable conductive material, and a combination thereof. In some embodiments, gate metal fill layer can include a substantially fluorine-free metal layer (e.g., fluorine-free W). The substantially fluorine-free metal layer can include an amount of fluorine contaminants less than about 5 atomic percent in the form of ions, atoms, and/or molecules.

In some embodiments, STI regions 117, first and second and ESL 116A and 116B, and first and second ILD layer 118A and 118B, can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ), and any other suitable insulating material.

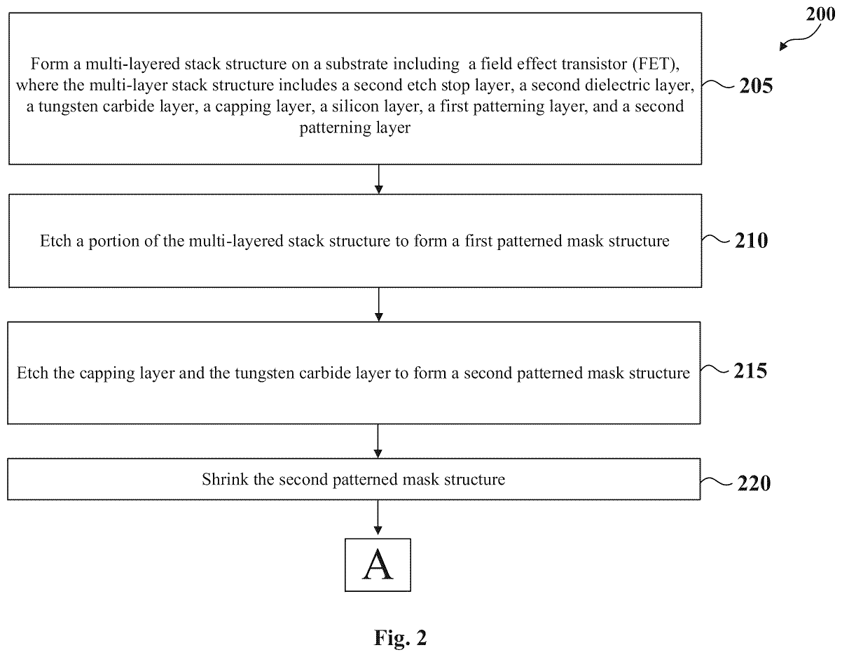

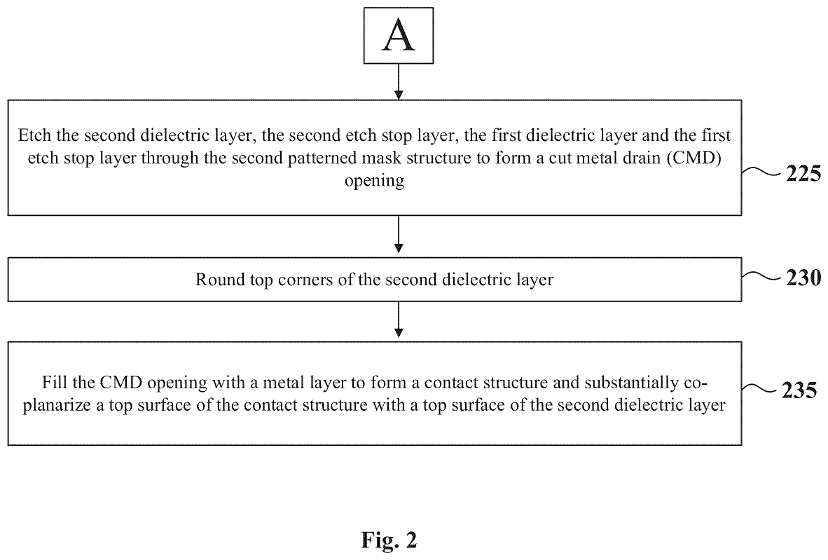

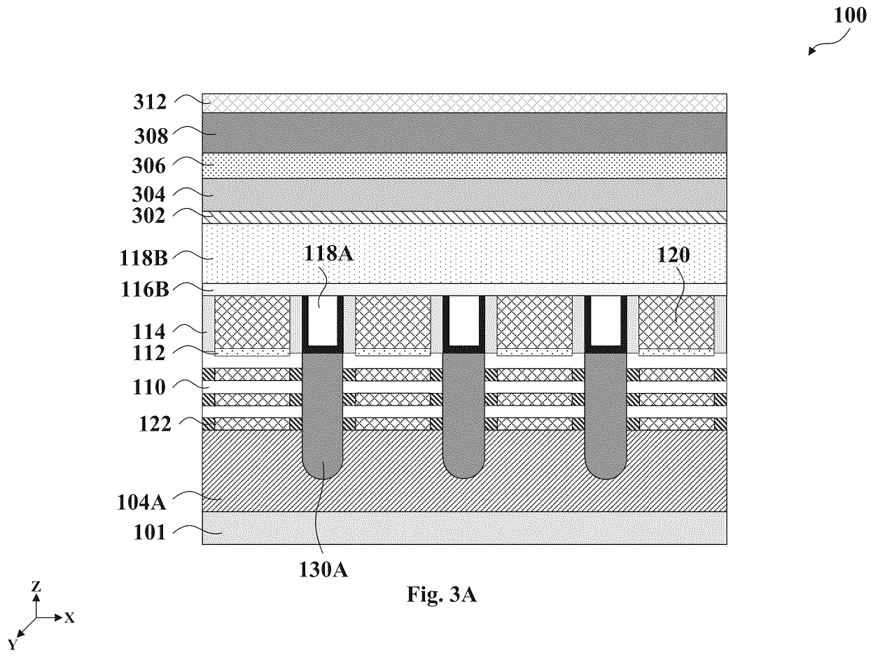

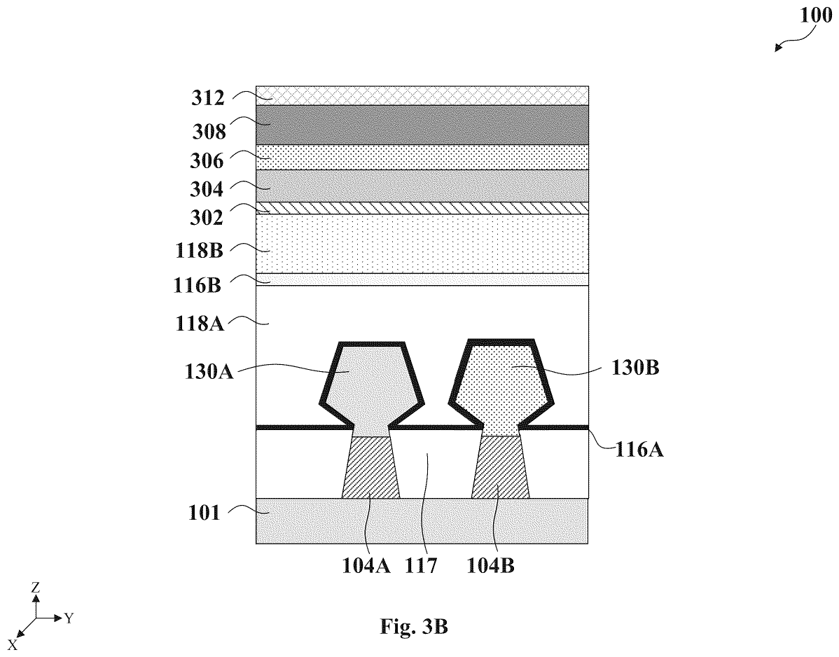

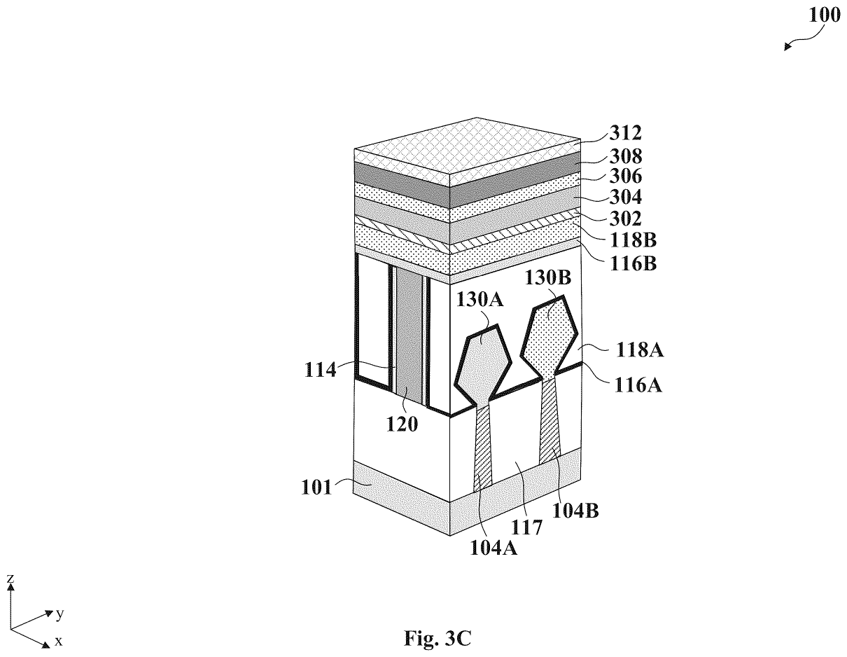

FIG. 2 is a flow diagram of an example method 200 for fabricating semiconductor device 100 as shown in FIGS. 1A-1C, according to some embodiments. For illustrative purposes, the operations illustrated in FIG. 2 will be described with reference to the example fabrication process for fabricating semiconductor device 100 as illustrated in FIGS. 3A-11A, 3B-11B, 3C-11C, 5D-7D, 5E-7E, and 5F-7F. FIGS. 3A-11A are cross-sectional views of semiconductor device 100 along line A-A of FIG. 1A at various stages of fabrication, according to some embodiments. FIGS. 3A-11A show a cross section of semiconductor device 100. FIGS. 3B-11B are cross-sectional views of semiconductor device 100 along line B-B of FIG. 1A at various stages of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. Elements in FIGS. 3A-11A, 3B-11B, 3C-11C, and 8D-8F with the same annotations as elements in FIGS. 1A-1C are described above.

The method 200 begins at operation 205 by forming a multi-layer stack structure on a substrate, where the substrate includes a FET. For example, as shown in FIGS. 3A-3C, a substrate 101 with a GAA FET is provided. A multi-layer stack structure can be formed on the GAA FET. Forming the multi-layer stack structure can include sequential operations of (i) depositing second ESL 116B on first dielectric layer 118A, (ii) depositing second ILD layer 118B, (iii) depositing tungsten carbide (WC) layer 302, (iv) depositing capping layer 304, (v) depositing silicon layer 306, (vi) depositing first patterning layer 308, and (vii) depositing second patterning layer 312.

In some embodiments, WC layer 302 can have a Young's modulus of about 197 GPa. In subsequent processing operations, WC layer 302 can be used as a hard mask layer for etching underlying layers in the multi-layer stack structure. The high Young's modulus of WC layer 302 can alleviate pattern weakness. Additionally, it can mitigate pattern weakness transferred from first patterning layer 308 and second patterning layer 312. In some embodiments WC layer 302 can be deposited by a plasma-enhanced chemical vapor deposition (PECVD) process. In some embodiments, the PECVD process for WC layer deposition can be performed by co-flowing tungsten fluoride (WF₃) and methane (CH₄) at a temperature between about 300 °C and about 400 °C. In some embodiments, WC layer can have a density of about 0.7 gm/cm³.

As an alternative to WC, in some embodiments a metal-based layer, such as tungsten (W), titanium nitride (TiN), titanium carbide (TiC), or tungsten nitride (WN) can be used, implying that instead of WC layer 302, a W layer, a TiN layer, a TiC layer, or a WN layer can be used. In some embodiments, W layer can be deposited by PECVD process by co-flowing WF₆ with H2. In some embodiments, W can be deposited by PECVD by co-flowing WCls and H₂. In some embodiments, W layer can be deposited by sputtering.

In some embodiments, capping layer 304 can be used as a hard mask layer in subsequent processing operations. Capping layer 304 can be formed of one or more of silicon oxide (SiO₂) or silicon oxycarbonitride (SiOCN). Capping layer 304 formed of, for example, SiO₂ and can have a Young's modulus of about 66 GPa. In some embodiments, first patterning layer 308 can include amorphous carbon. In some embodiments, first patterning layer 308 can be formed of a carbon-based material. In some embodiments, the carbon-based material can be deposited by chemical vapor deposition (CVD) or by a spin coating process. First patterning layer 308 can have a Young's modulus between, for example, between about 4.4 GPa and about 10 GPa. In some embodiments, second patterning layer 312 can be formed of SiOC and can be deposited by CVD.

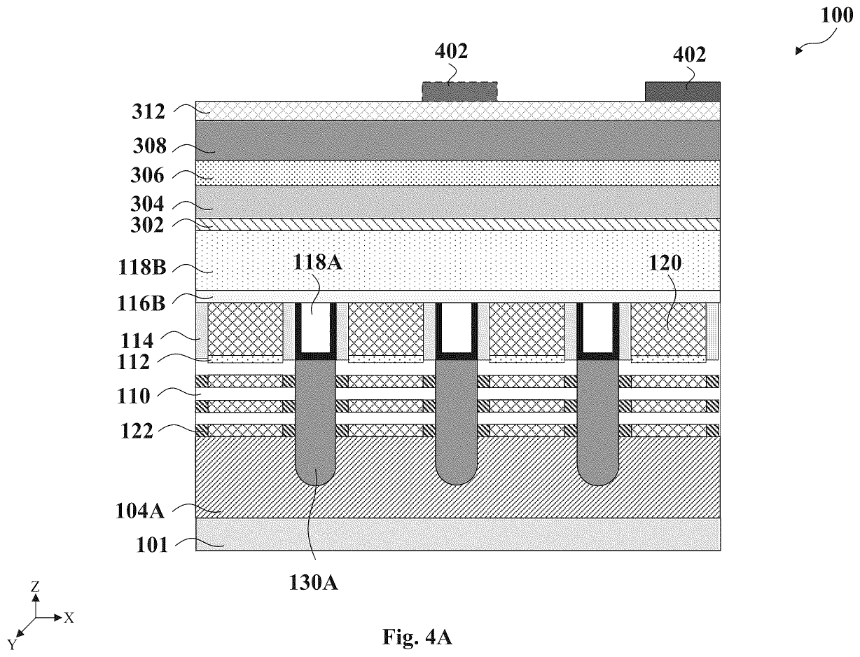

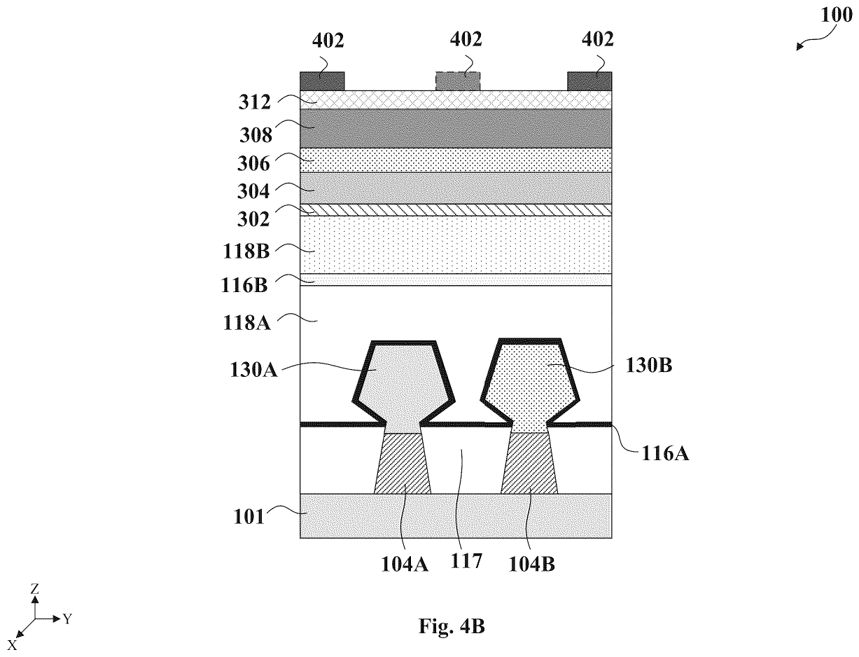

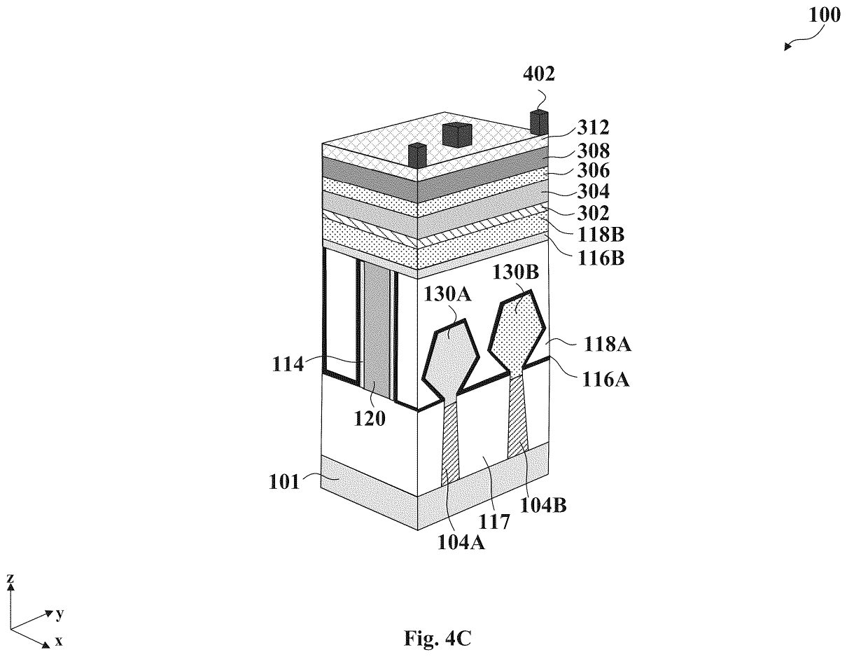

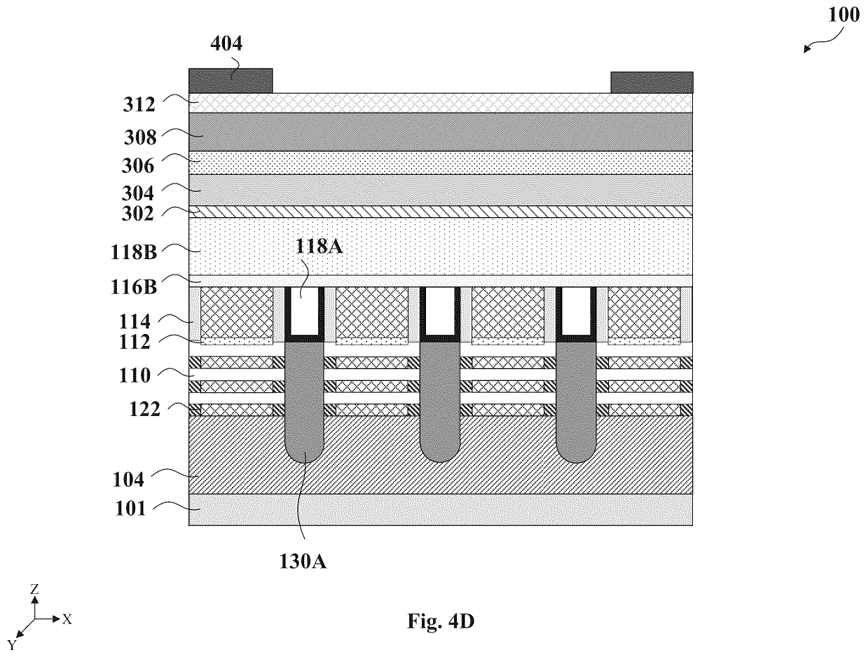

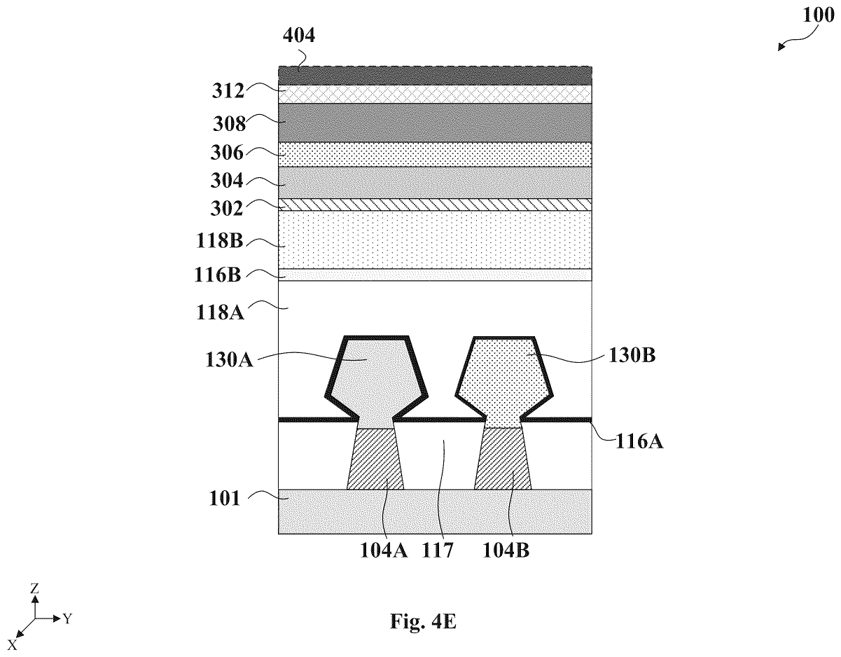

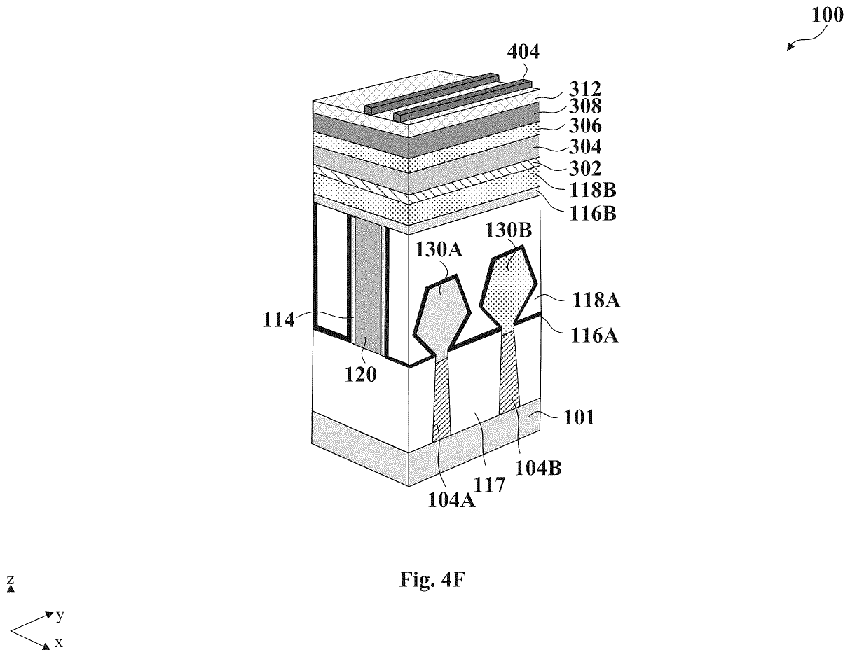

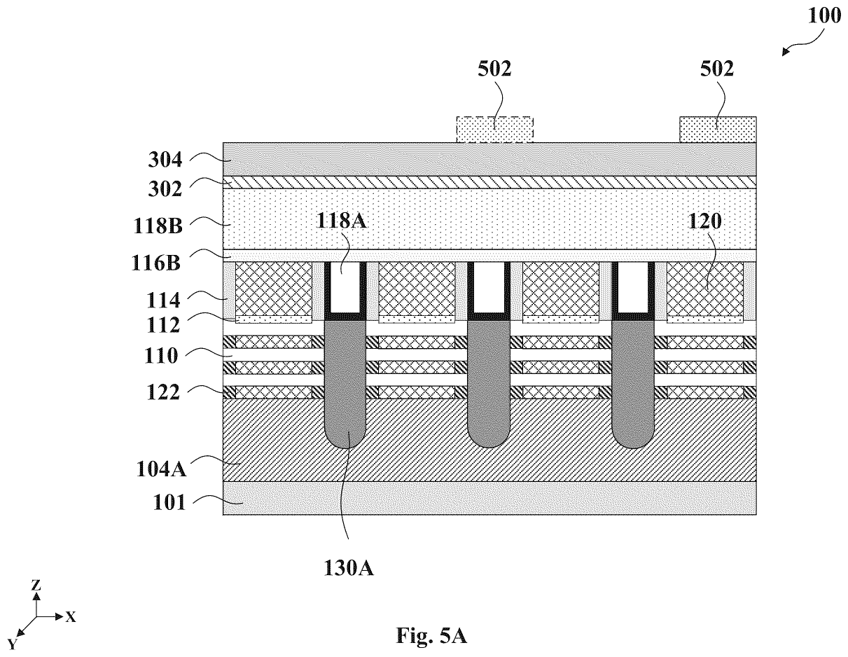

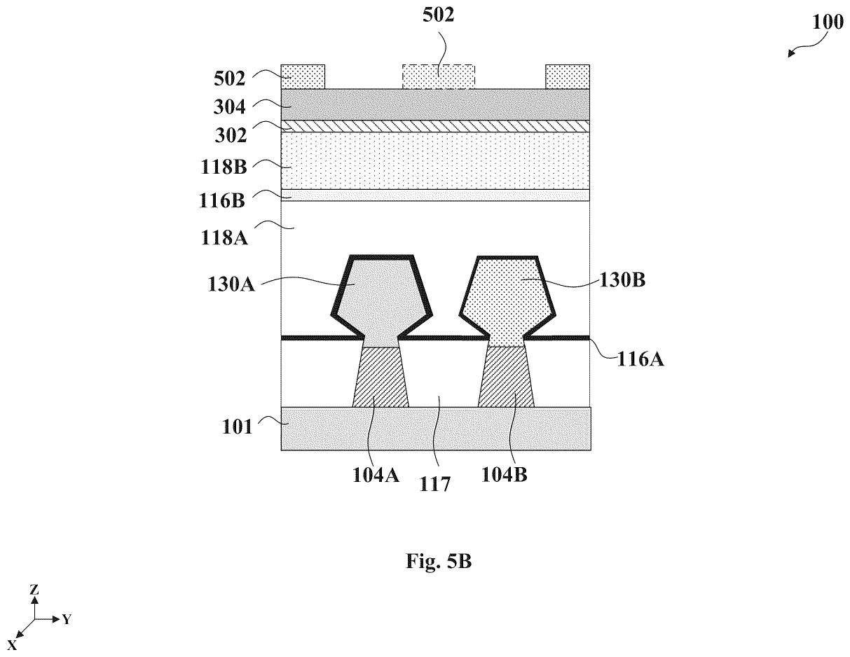

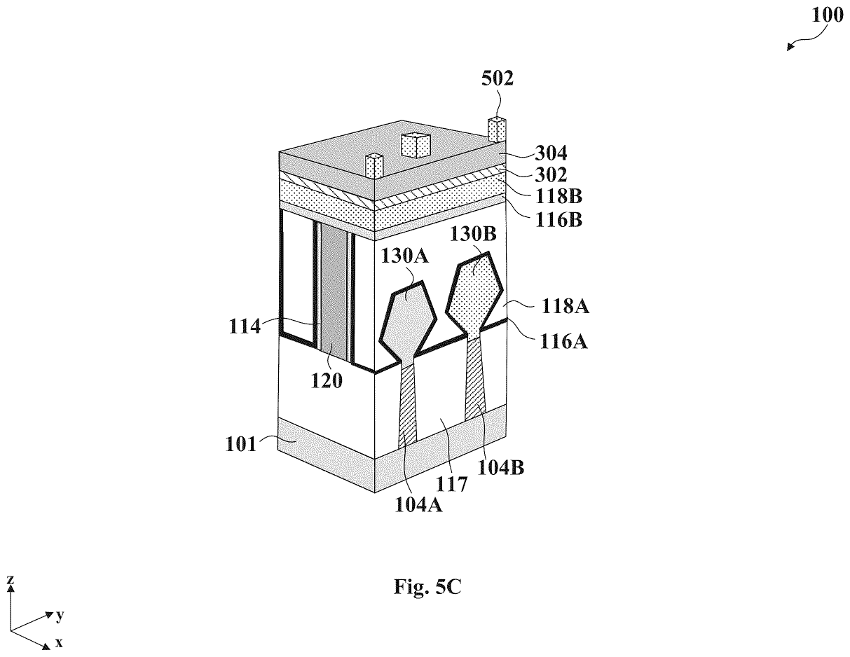

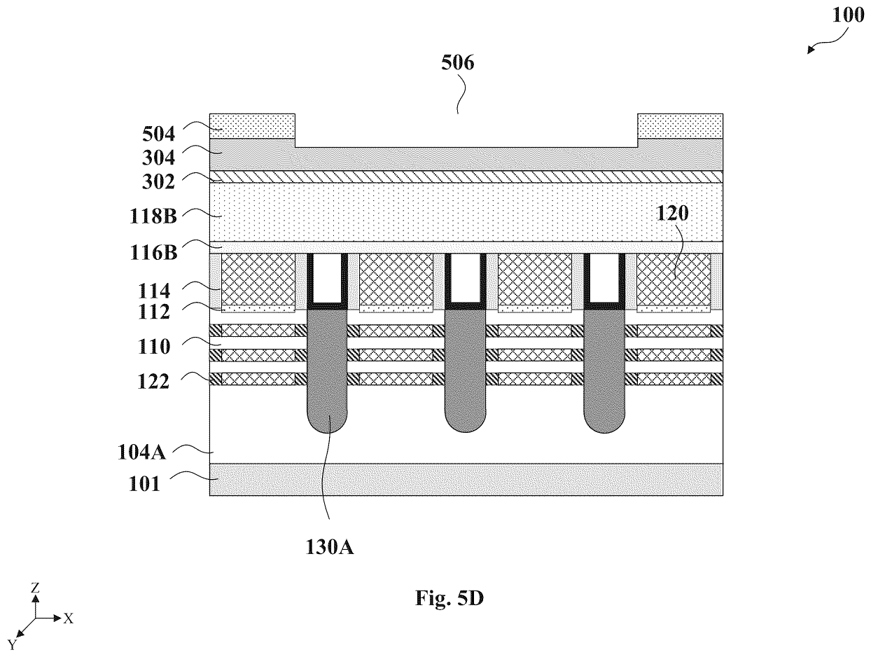

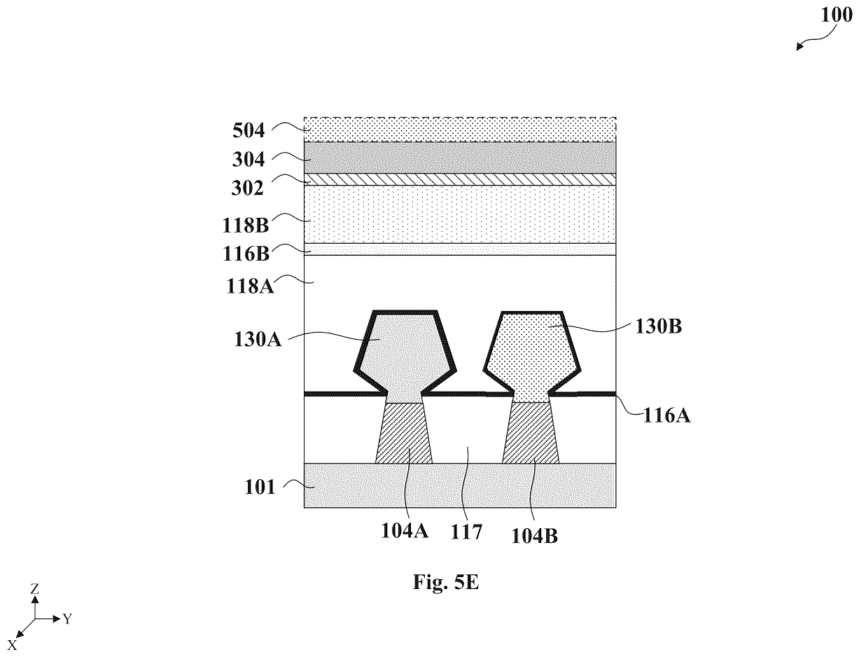

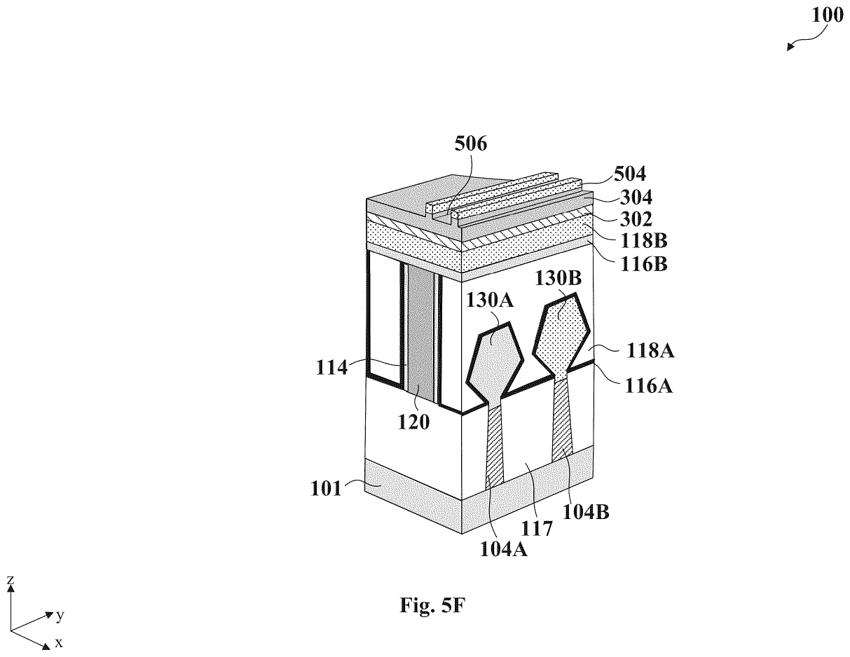

Referring to FIG. 2, in operation 210, a portion of the multi-layered stack structure is etched to form a first patterned mask structure. The first patterned mask structure can be formed of silicon layer 306. The following paragraphs describe two methods of forming the first patterned mask structures. Using a first method, according to some embodiments, first patterned mask structure 402 can be formed using the operations illustrated in FIGS. 4A-4C and 5A-5C. Using a second method, according to some embodiments, first patterned mask structure 404 can be formed using the operations illustrated in FIGS. 4D-4F and 5D-5F.

According to some embodiments, a process of forming first patterned mask structure 502 by the first method can include depositing and patterning a photoresist layer to form first patterned mask 402, as shown in FIGS. 4A-4C. The process of forming first patterned mask structure 502 using the first method can further include (i) etching areas of second patterning layer 312 not protected by first patterned mask 402 to form the first patterned mask on second patterning layer 312, (ii) etching areas of first patterning layer 308 not protected by the first patterned mask on second patterning layer 312 to form the first patterned mask on silicon layer 306, and (iii) etching areas of silicon layer 306 not protected by the first patterned mask on first patterning layer 308 to form first patterned mask structure 502. The result of operations (i)-(iii) of the first method is shown in FIGS. 5A-5C. First patterned mask structure 502 can be formed of silicon layer 306. During the above described process of sequentially patterning and etching a portion of the multi-layer stack structure to form first patterned mask structure 502, second patterning layer 312, first patterning layer 308, and silicon layer 306 can be etched using an anisotropic wet or dry etching process. In some embodiments, first patterning layer 308, second pattering layer 312 and silicon layer 306 can be etched by a hexafluorobutadiene (C₄F₆) or tetrafluoromethane (CF₄) based dry etching process. The dry etching process can use one or more of carbon monoxide (CO), oxygen (O₂), argon (Ar), or nitrogen (N₂) to remove etch byproducts. In some embodiments, first patterning layer 308, second pattering layer 312 and silicon layer 306 can be etched by a dry etching process using one or more of fluoromethane (CH₃F), difluoromethane (CH₂F₂), or octafluorocyclobutane (C₄F₈). In some embodiments, the plasma-based etch can be performed with voltage bias between about 30V and about 1000V. In some embodiments, the dry etching process can use a power between about 50 watts and about 1000 watts and a radio frequency (RF) between about 400 kHz and about 60 MHz. In some embodiments, the etching can be performed at a temperature between about −150 °C to about 200 °C.

After forming first patterned mask structure 502, first patterning layer 308 and second patterning layer 312 can be removed. In some embodiments, the first patterning layer 308 can be removed by a dry etch process using O₂ or isodiazene (N₂H₂). In some embodiments, second patterning layer 312 gets removed during the formation of first patterned mask structure 502. In some embodiments, first patterned mask structure 502 can define the CD (width) of isolation structure 132 between adjacent S/D contact structures.

According to some embodiments, another process of forming first patterned mask structure 504 by the second method can include depositing and patterning a photoresist layer to form first patterned mask 404, where the first patterned mask extends along the y-axis, as shown in FIGS. 4D-4F. A process of forming first patterned mask structure 504, according to the second method, can further include (i) etching areas of second patterning layer 312 not protected by photoresist layer 404 to transfer the first patterned mask to second patterning layer 312, (ii) etching areas of first patterning layer 308 not protected by second patterning layer 312 to transfer the first patterned mask to first patterning layer 308, (iii) etching areas of silicon layer 306 and a portion of capping layer 304 not protected by the first patterned mask on first patterning layer 308 to form first patterned mask structures 504. The result of operations (i)-(iii) of the second is shown in FIGS. 5D-5F. First patterned mask structure 504 can include openings 506. After forming first patterned structure 504, first patterning layer 308 overlying first patterned mask structure 504 can be removed. In some embodiments, the first patterning layer 308 can be removed by a dry etch process using O₂ or isodiazene (N₂H₂). In some embodiments, second patterning layer 312 gets removed during the formation of first patterned mask structure 504.

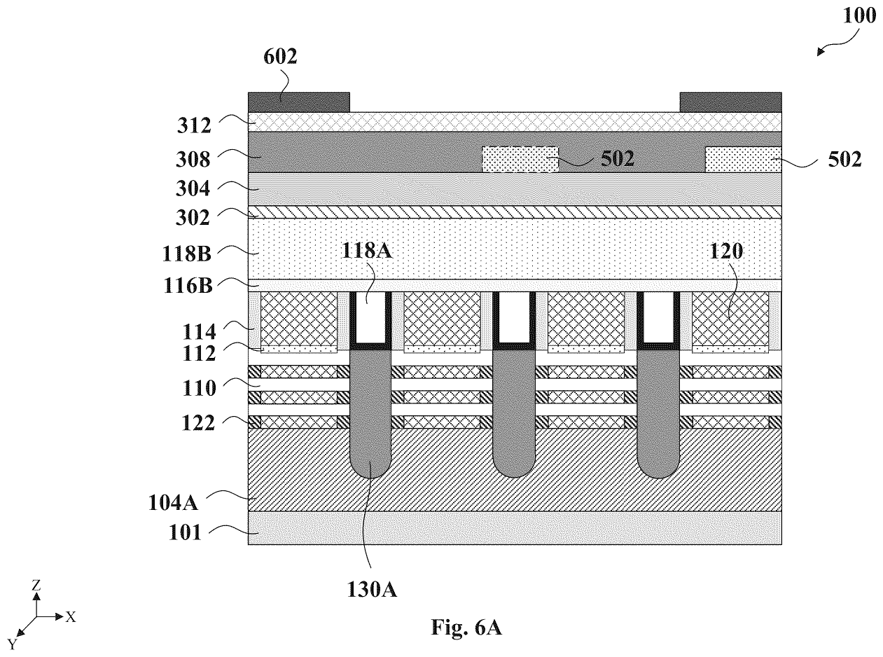

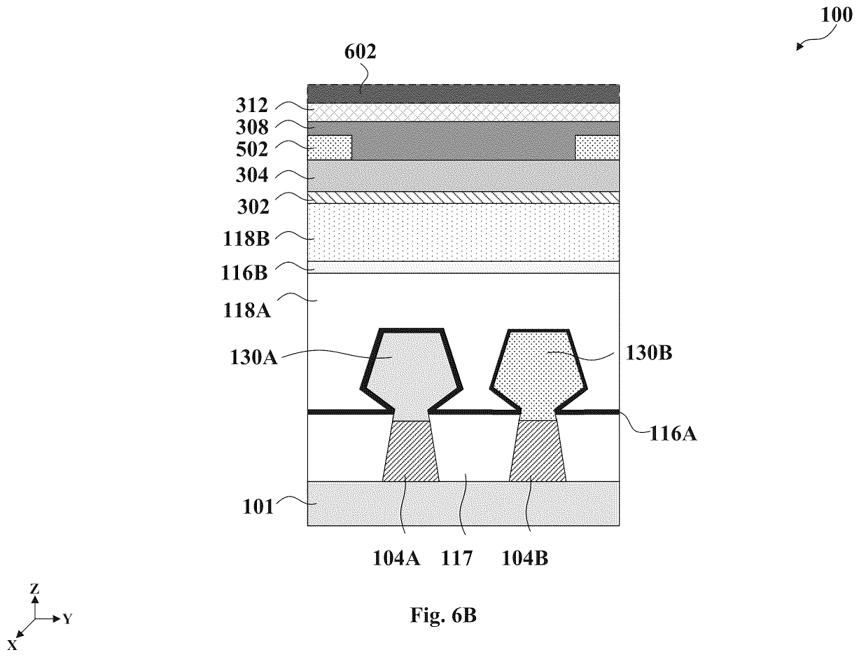

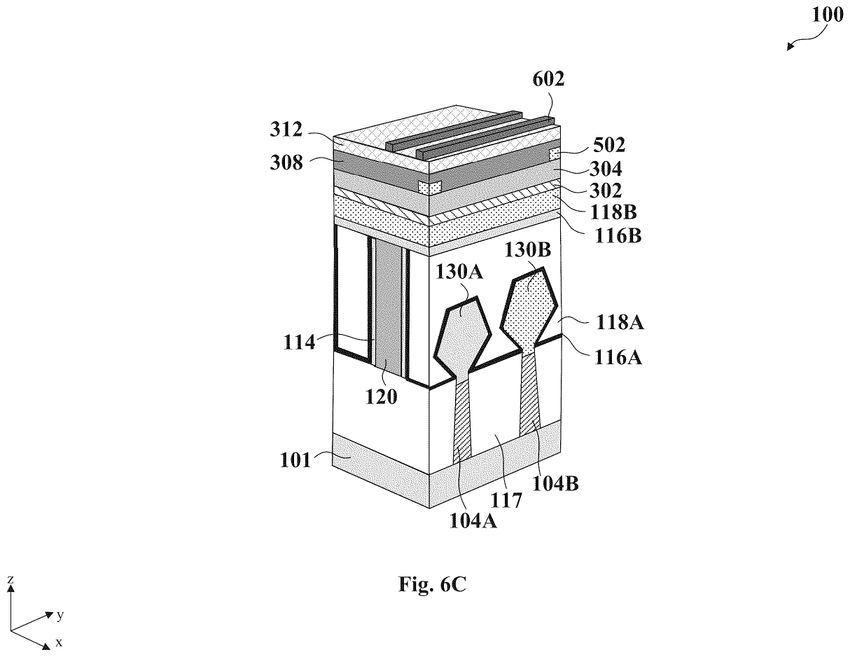

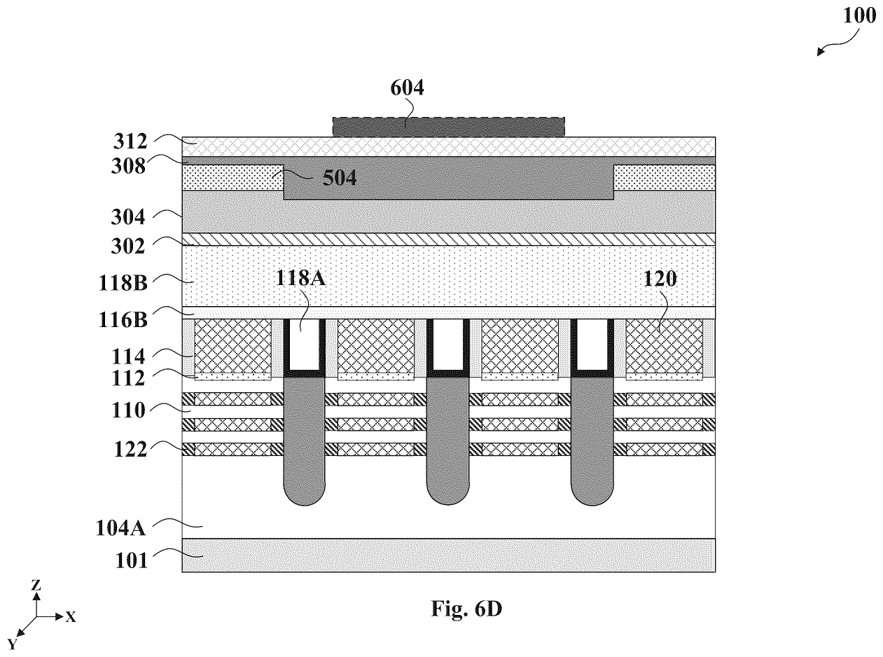

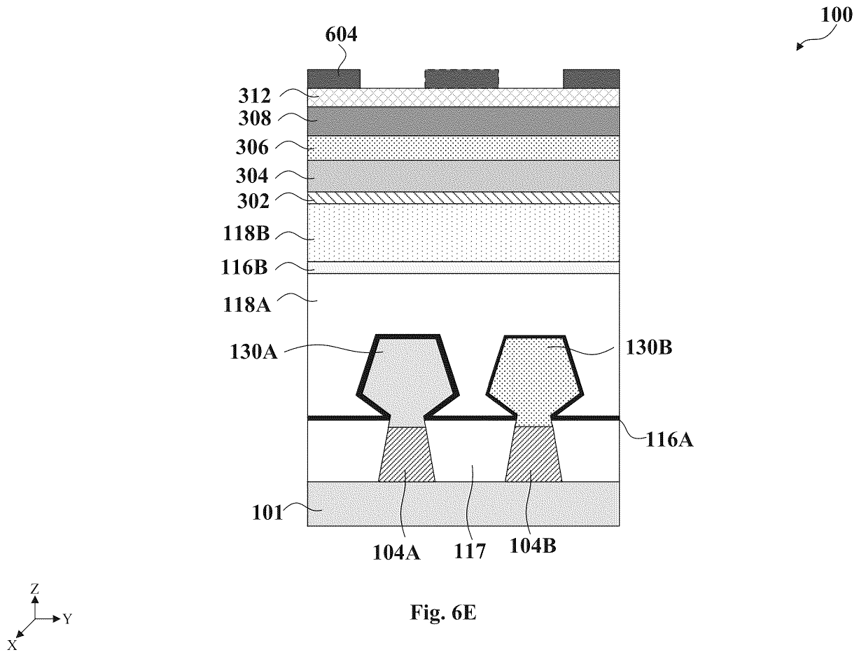

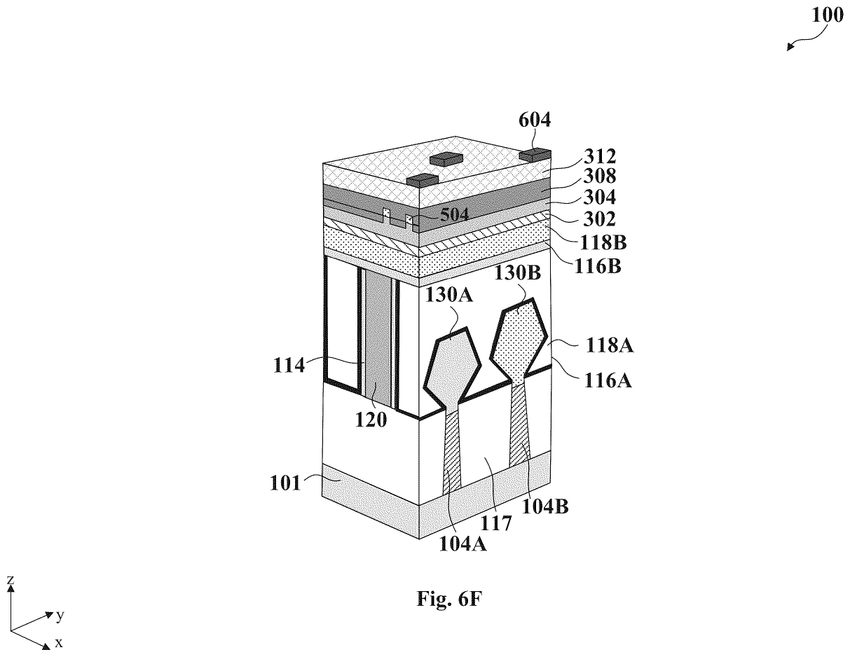

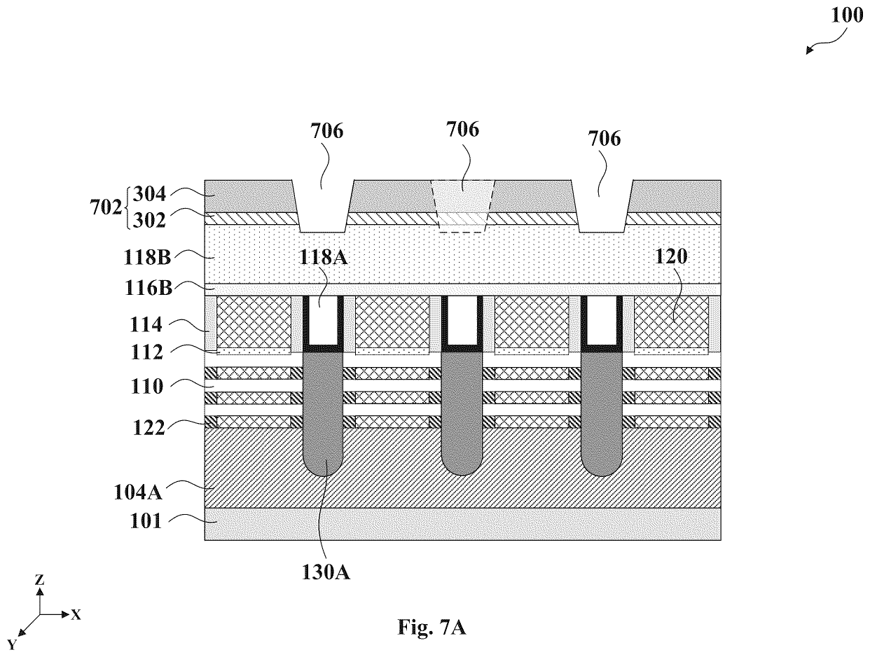

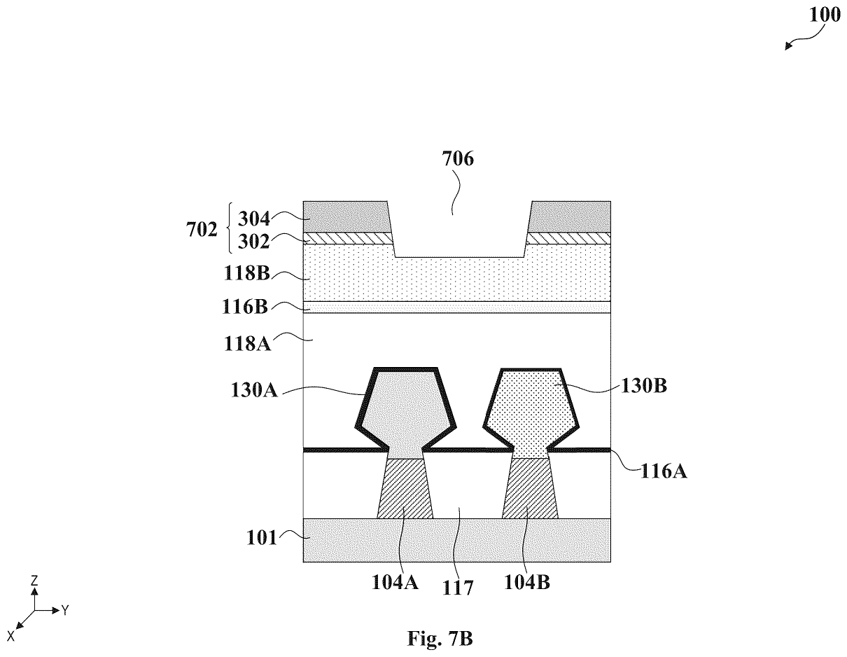

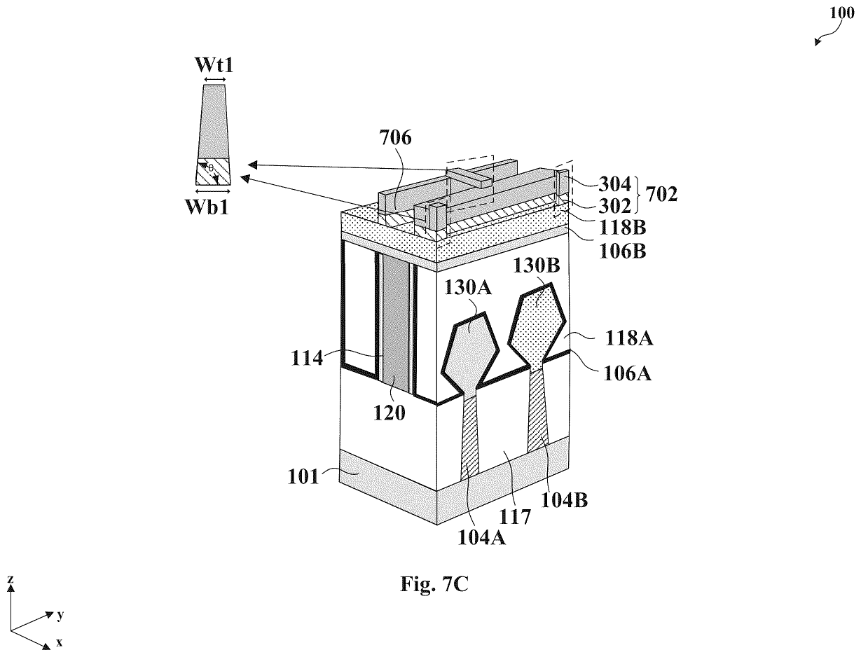

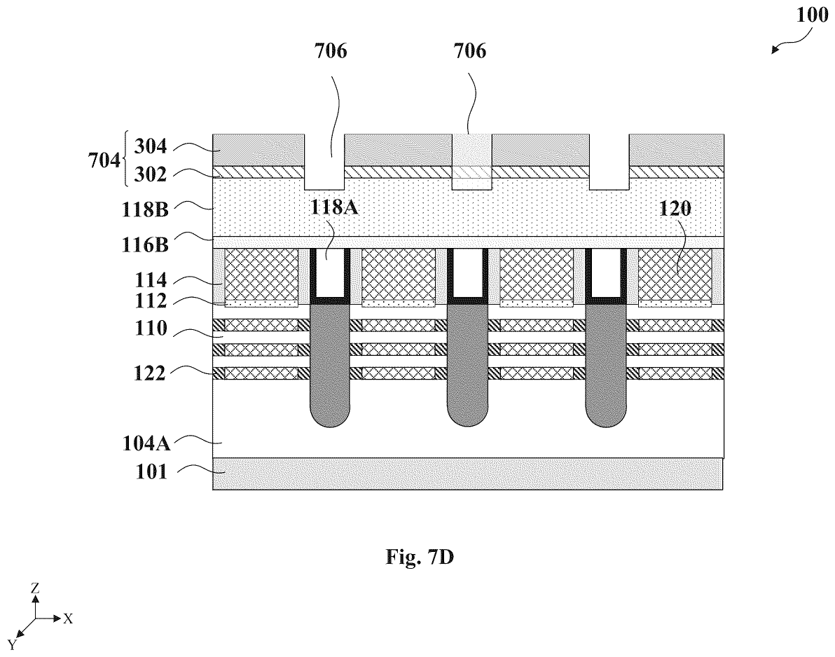

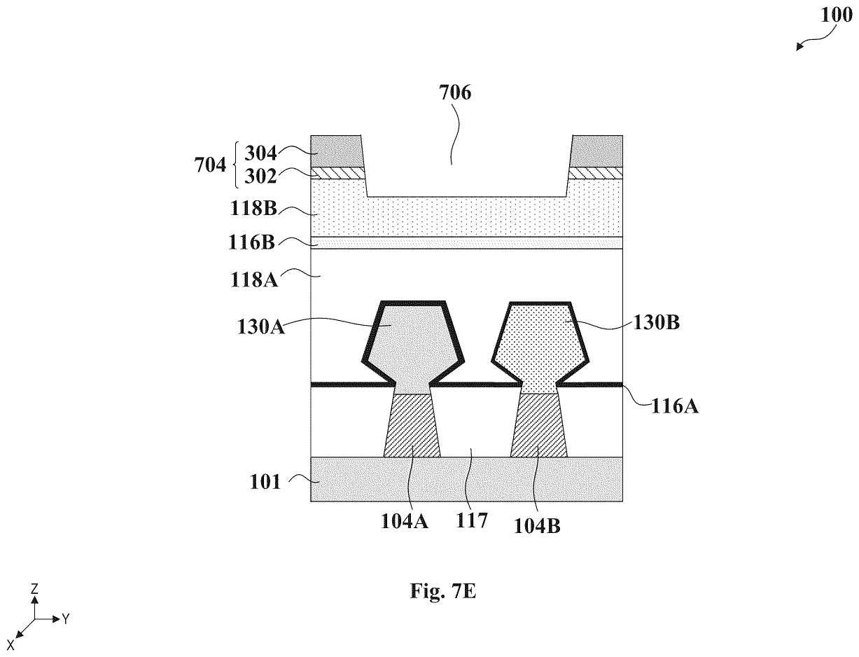

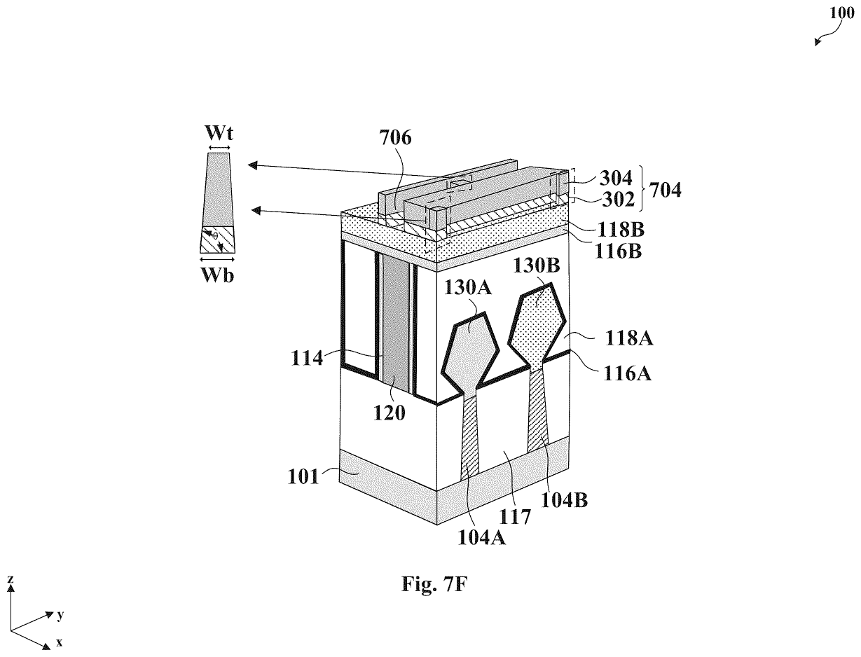

Referring to FIG. 2, in operation 215, the capping layer and the WC layer are patterned and etched to form a second patterned mask structure. The second patterned mask structure can be formed of capping layer 304 and WC layer 302. The following paragraphs describe two methods of forming the second patterned mask structure. Using a first method, according to some embodiments, second patterned mask structure 702 can be formed using the operations illustrated in FIGS. 6A-6C and 7A-7C. Using a second method, according to some embodiments, second patterned mask structure 704 can be formed using the operations illustrated in FIGS. 6D-6F and 7D-7F.

Forming second patterned mask structure 702 by the first method, according to some embodiments, can include (i) depositing first patterning layer 308 on the first patterned mask structure 502 so that first patterned mask structure 502 can be covered by first patterning layer 308, and (ii) depositing second patterning layer 312 on first patterning layer 308, as shown in FIGS. 6A-6C, and (iii) depositing and patterning a photoresist layer on second patterning layer 312 to form second patterned mask 602, where second patterned mask 602 extends along a y-axis. The results of operations are shown in FIGS. 6A-6C, According to some embodiments, the first method of forming second patterned mask structure 702, can further include (iv) etching second patterning layer 312 and first patterning layer 308, through second patterned mask 602, and (v) etching capping layer 304, WC layer 302 and a portion of second ILD layer 118B through first patterned mask structure 502 and second patterned mask 602 to form second patterned mask structure 702. The results of operations (iii) and (iv) are shown in FIGS. 7A-7C. After forming second patterned mask structure 702, first patterning layer 308 and second patterning layer 312 can be removed. Second patterned mask structure 702 can be formed of capping layer 304 and WC layer 302. In some embodiments, second patterned mask structure 702 can include openings 706. Second patterned mask structure 702 can act as a hard mask for forming cut metal drain (CMD) openings in subsequent operations. In some embodiments, first patterned mask structure 502 can be aligned to second patterned mask 602 using lithographic alignment.

Forming second patterned mask structure 704 by the second method, according to some embodiments, can include (i) depositing first patterning layer 308 on first patterned mask structure 504 so that first patterned mask structure 504 is covered by first patterning layer 308, (ii) depositing second patterning layer 312 on first patterning layer 308, (iii) depositing and patterning a photoresist layer on second patterning layer 312 to form a second patterned mask 604. The results of operations (i)-(iii) are shown in FIGS. 6D-6F. According to some embodiments, the second method of forming second patterned mask structure 704, can further include (iv) etching second patterning layer 312 and first patterning layer 308 through first patterned mask 604, and (v) etching capping layer 304, WC layer 302 and a portion of second ILD layer 118B through first patterned mask 604 and first patterned mask structure 504 to form second patterned mask structure 704. The results of operations (iv) and (v) are shown in FIGS. 7D-7F. After forming second patterned mask structure 704, first patterning layer 308 and second patterning layer 312 can be removed. Second patterned mask structure 704 can be formed of capping layer 304 and WC layer 302. In some embodiments, second patterned mask structure 704 can include openings 706. In some embodiments, second patterned mask structure 704 can act as a hard mask for forming CMD openings in subsequent operations.

Either one of second patterned mask structure 702 or 704 can be used for subsequent operations of method 200. For example purposes, for the remaining disclosure, second patterned mask structure 702 or 704 will be referred to as “patterned mask structure 708.”

According to some embodiments, patterned mask structure 708 formed of capping layer 304 and WC layer 302 can have a tapered profile (as shown in the inset in FIGS. 7C and 7F). The tapered portion can have a top portion with width Wt1 and a bottom portion with width Wb1, where Wb1 can be greater than Wt1. In some embodiments, width Wt1 can be between about 7 nm and about 191 nm. In some embodiments, width Wb1 can be between about 8 nm and about 198 nm. Additionally, a ratio between width Wt1 and Wb1 can be between about 0.87 and about 0.96.

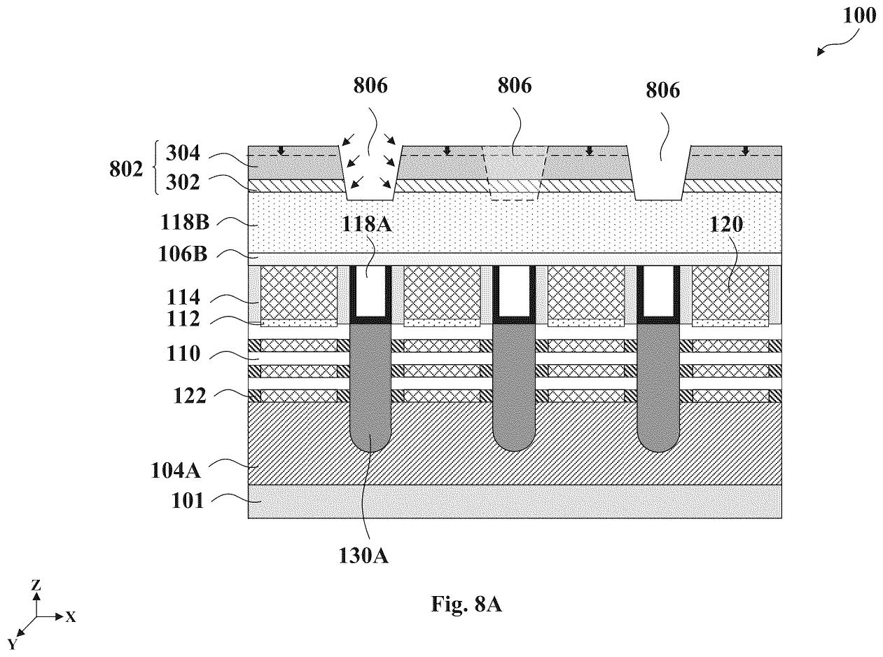

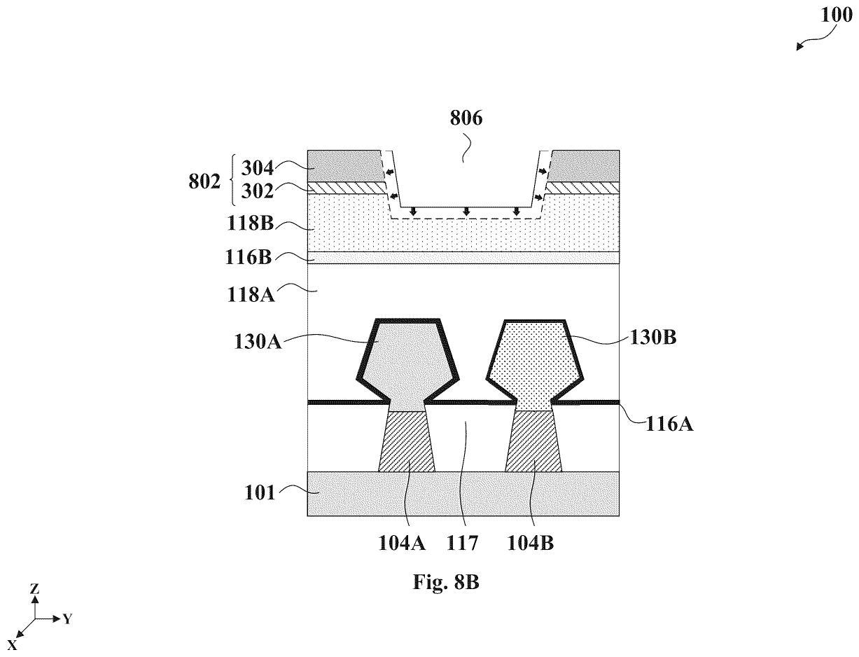

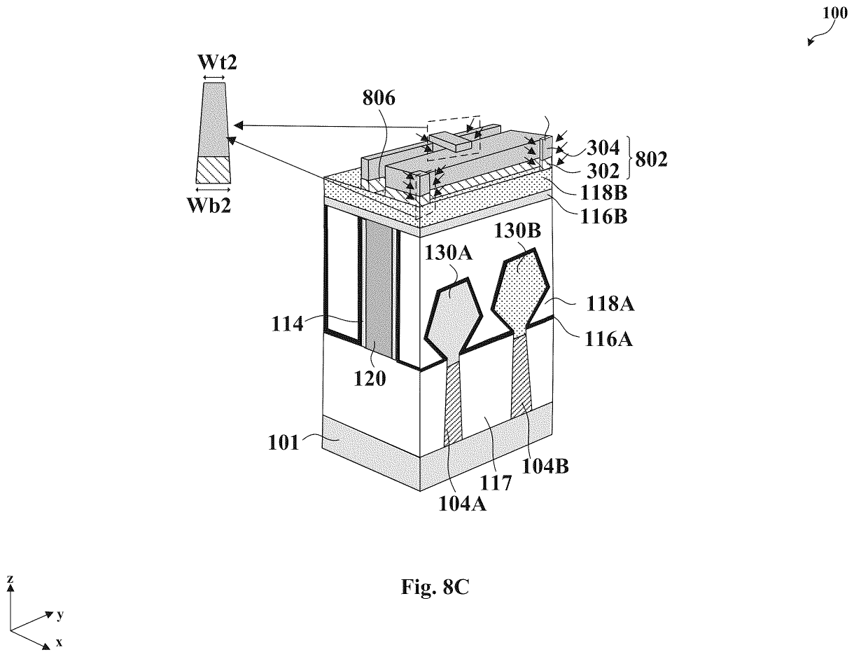

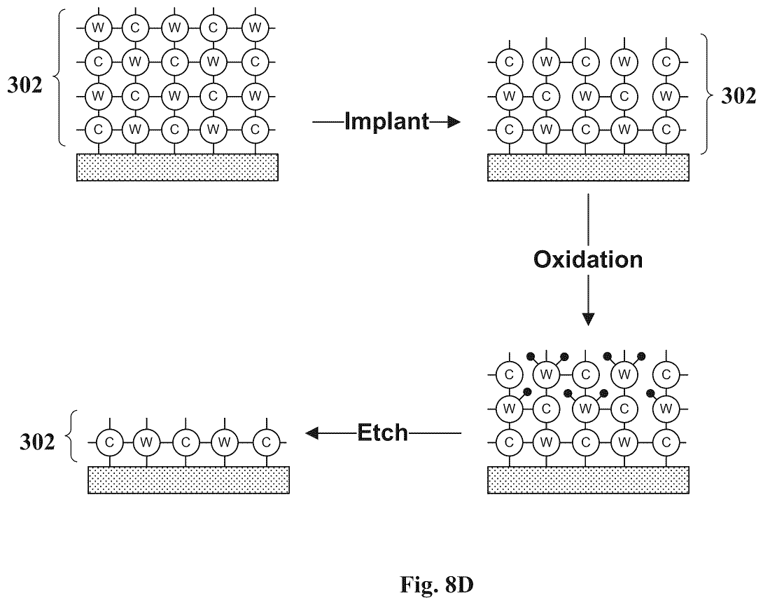

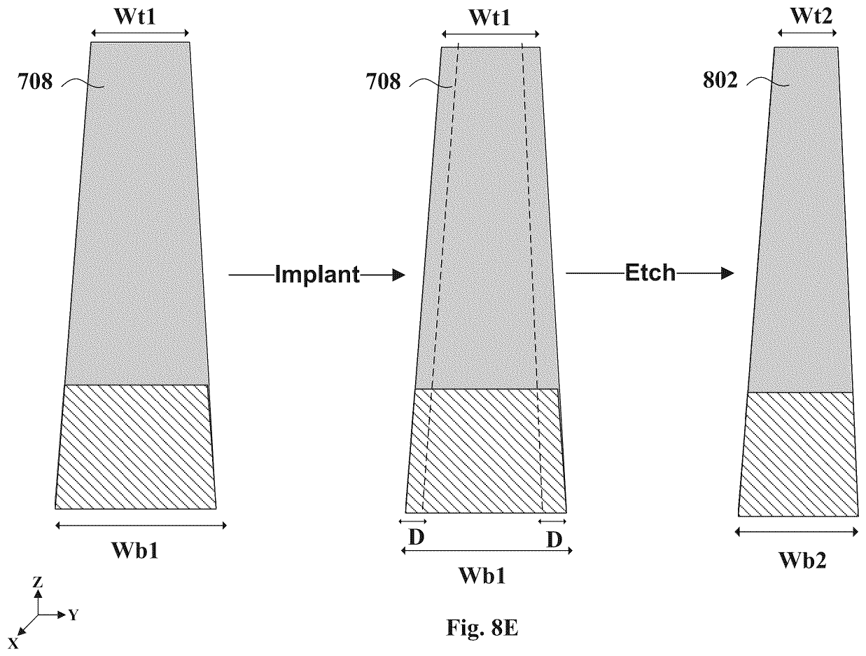

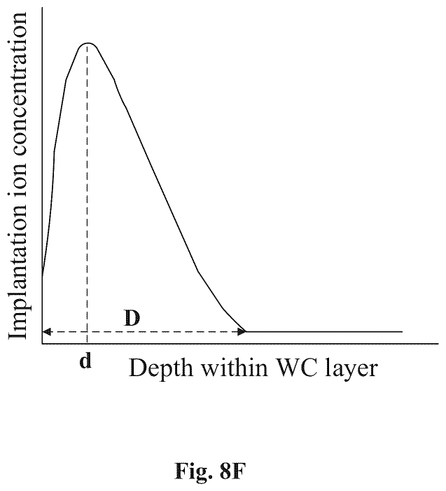

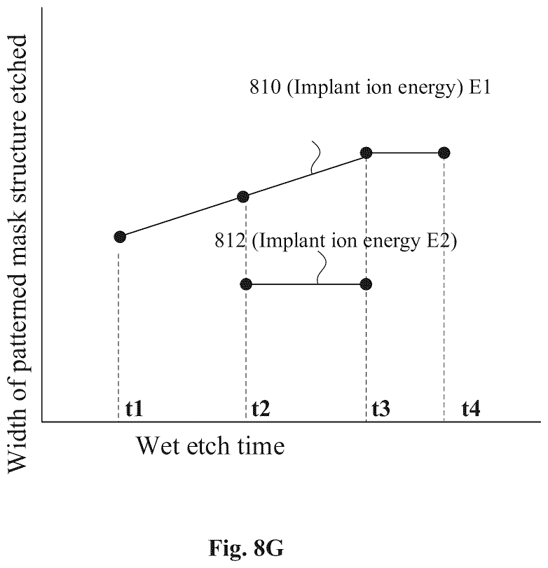

Referring to FIG. 2, in operation 220, a width of the patterned mask structure 708 formed of the capping layer and WC layer can be shrunk along the y-axis. In some embodiments, shrinking patterned mask structure 708 can include (a) performing a directional implant on sidewalls of patterned mask structure 708 to structurally damage a portion of capping layer 304 and WC layer 302, (b) oxidizing the structurally damaged portion of capping layer 304 and WC layer 302, and (c) etching the oxidized portion of capping layer 304 and WC layer 302, to form patterned mask structure 802. For example, as shown in FIGS. 8A-8C, a directional implant can be performed on capping layer 304 and WC layer 302 of patterned mask structure 708. To have the implantation ions impinge on the sidewalls of capping layer 304 and the sidewalls of WC layer 302, a directionality can be provided to the implantation ions. To implant both sidewalls of patterned mask structure 708 perpendicular to the y-axis, patterned mask structure 708 can be rotated after ion implanting one sidewall. In some embodiments, the directional implant can be performed with a tilt angle between about 2° and about 88° and a twist angle between about 10° and about 30°. The directional implant can be performed using ions, for example, argon (Ar), xenon (Xe), or oxygen (O₂) ions. In some embodiments, Ar ions can be accelerated and made to impinge on sidewalls of capping layer 304 and WC layer 302, as shown in FIGS. 8A-8C. The Ar ions can penetrate an outer portion of capping layer 304 and WC layer 302 causing structural damage. The structural damage can be prominent, for example, up to a depth D in an outer portion of capping layer 304 and WC layer 302, as shown in FIG. 8E. In some embodiments, the ion implantation can cause structural damage by breaking W—C bonds in a lattice of WC layer 302, as shown in FIG. 8D. In some embodiments, as shown in FIG. 8F, the maximum ion concentration can be found at a depth “d” from a surface of sidewall of WC layer 302. Depths “D’ and “d” can be varied by varying implantation energy of the ions. In some embodiments, the ion implantation energy can be between about 1 keV and about 10 keV. In some embodiments, during ion implantation, semiconductor device 100 can be held on an ion implantation platen maintained at a temperature between about 150 °C and about 600 °C. Performing ion implantation at a temperature greater than about 600 °C can deteriorate material layers forming the gate structure. In some embodiments, the ion implantation can be performed at a pressure between about 10⁻⁵ torr and about 10⁻⁷ torr. The ion implantation can be performed using an ion dose of, for example, about 10¹⁵ atoms/cm². For example, ion implantation can be performed with ion implantation energy about 2.5 keV and an ion dose of about 10¹⁵ atoms/cm².

In some embodiments, as shown in FIG. 8D, ion implantation can break W—C bonds in WC layer 302 to form dangling sites at W atoms in the WC lattice. These dangling sites can be susceptible to oxidation. In some embodiments, oxygen atoms from the air can attach at these dangling sites to form W—O bonds, as shown in FIG. 8D. Formation of W—O bonds is critical for the subsequent wet etching process. W—O bonds can be formed at various W sites within the ion implanted portion (within depth D) of WC layer 302.

In some embodiments, the oxidized portion of WC layer 302 can be etched using a wet etching process. A thickness of the oxidized portion of WC layer can be substantially equal to a thickness of the ion implanted portion of WC layer 302. In other words, the oxidized portion of WC layer can extend, for example, up to a depth D from an outer sidewall of WC layer 302. An outer portion of capping layer 304 can undergo a similar oxidation process. In some embodiments, the oxidized portion of capping layer 304 and the oxidized portion of WC layer 302 can be wet etched using a diluted ammonium hydroxide (dNH₄OH) solution. The dNH₄OH solution can have water (H₂O) and NH₄OH in a ratio between about 1:1 and about 1:2000. For example, capping layer 304 and WC layer 302 ion implanted with an ion energy of about 2.5 keV and an ion dose of about 10¹⁵ atoms/cm² can be etched by a dNH4OH solution in about 55 seconds to about 65 seconds. In some embodiments, the dNH4OH solution can be heated to a temperature between about 20 °C and about 70 °C. The wet etching process removes the oxidized portion of capping layer 304 and the oxidized portion of WC layer 302. The wet etching process does not remove the un-oxidized portion of capping layer 304 and WC layer 302. Therefore, increasing the etching time beyond about 65 seconds may not further etch the capping layer 304 and WC layer 302.

In some embodiments, the oxidized portion of capping layer 304 and the oxidized portion of WC layer 302 can be wet etched using a diluted ammonium hydroxide (dNH₄OH) solution and a diluted hydrogen fluoride (dHF) solution. For example, the oxidized portion of capping layer 304 and the oxidized portion of WC layer 302 ion implanted with an ion energy of about 2.5 keV and an ion dose of about 10¹⁵ atoms/cm² can be etched by wet etching in a dNH4OH solution for about 40 seconds and wet etching in a dHF solution for about 30 seconds.

FIG. 8E illustrates a change in width of patterned mask structure 708 during the shrinking process. In some embodiments, as shown in FIG. 8E, patterned mask structure can have a tapered profile with a top portion with width Wt1 and a bottom portion with width Wb1. Ion implantation can cause structural damage to an outer portion of patterned mask structure 708. The structurally damaged portion can extend up to a depth D from an outer sidewall surface of patterned mask structure 708. The structurally damaged portion of patterned mask structure 708, with depth D, can undergo oxidation by reacting with oxygen from the air. The oxidized portion of patterned mask structure 708, with depth D, can be etched to form patterned mask structure 802 with a top portion with width Wt2 and a bottom portion with width Wb2. In some embodiments, Wt2 can be between about 4 nm and about 181 nm, and Wb2 can be between about 5 nm and about 188 nm. In some embodiments, a ratio of Wt2 to Wb2 can be between about 0.8 and about 0.9.

In some embodiments, a time required to etch the oxidized portion of capping layer 304 and WC layer 302 can be determined by depth D of the implanted portion of capping layer 304 and WC layer 302. Depth D of the implanted portion of capping layer 304 and WC layer 302 in turn can depend on the ion implant energy. FIG. 8G illustrates a thickness of capping layer 304 and WC layer 302 vs wet etching time, where the thickness is along the y-axis. Curve 810 represents capping layer 304 and WC layer 302 ion implanted with ion energy E1 and having an ion implanted portion with depth d1. Curve 812 represents capping layer 304 and WC layer 302 ion implanted with ion energy E2 and having an ion implanted portion with depth d2. With reference to FIG. 8G, E1 is greater than E2. Accordingly, d1 is greater than d2. In some embodiments, E1 can be about 2.5 keV and E2 can be about 1.5 keV. It can take time between time t1 and time t3 to wet etch the ion implanted portion of capping layer 304 and WC layer 302 (depth d1) represented by curve 810. As shown in FIG. 8G, between time t1 and time t3, depth d1 of capping layer 304 and WC layer 302 has been etched. No further etching takes placed between time t3 and t4, because the wet etch does not etch non-ion implanted portion of capping layer 304 and WC layer 302 represented by curve 810. The inner portion of capping layer 304 and WC layer 302 represented by curve 810 is not removed by the wet etch process. In another example, as shown in FIG. 8G, it can take time between time t1 time t2 to wet etch the ion implanted portion of capping layer 304 and WC layer 302 (depth d2) represented by curve 812. No further etching takes place between time t2 and time t3, because the wet etch does not etch non-ion implanted portion of capping layer 304 and WC layer 302 represented by curve 812.

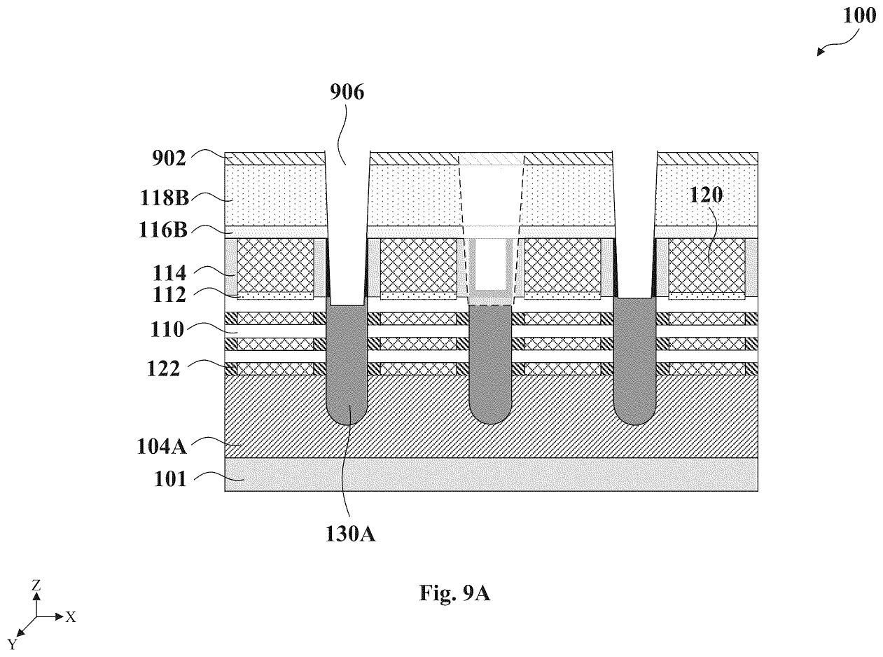

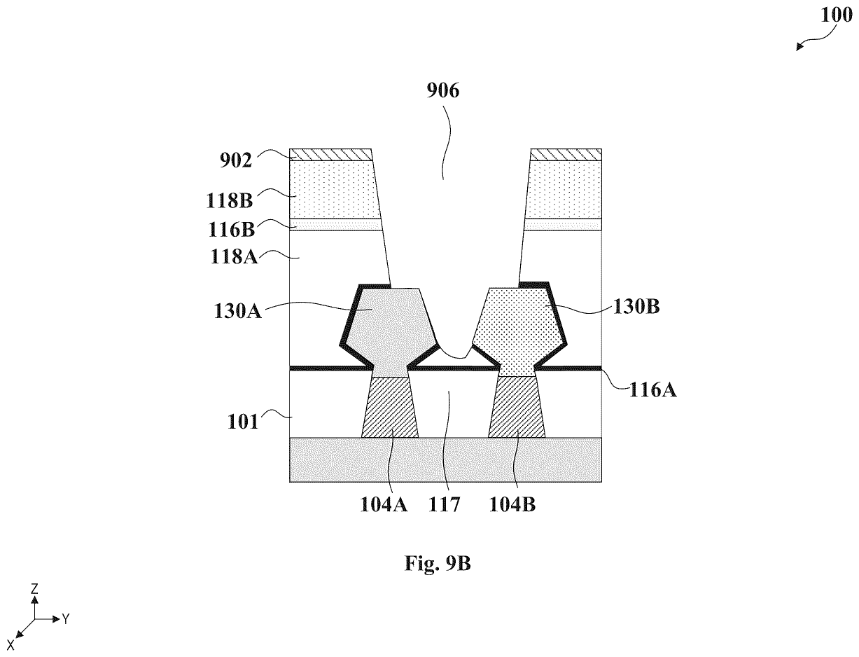

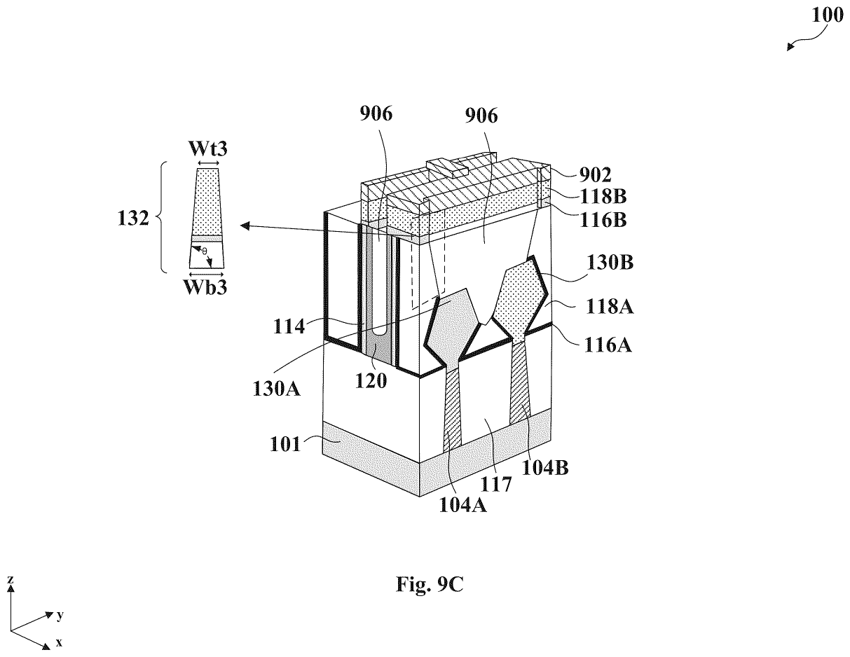

In some embodiments, after shrinking patterned mask structure 708 to form patterned mask structure 802, capping layer 304 can be removed. For example, as shown in FIG. 9C, capping layer 304 can be removed from patterned mask structure 802, to form patterned mask structure 902. Patterned mask structure 902 can act as hard mask layer for subsequent etching processes. During formation of patterned mask structure 902, capping layer 304 is removed.

Referring to FIG. 2, in operation 225, the second ILD layer, the second ESL, the first dielectric layer, and the first ESL are etched through patterned mask structure 902, to form opening 906. In some embodiments, as shown in FIGS. 9A, 9B, and 9C, WC layer 302 can act as the hard mask layer for anisotropically etching second ILD layer 118B, second ESL 116B, first dielectric layer 118A, and first ESL 116A to form opening 906. In some embodiments, the anisotropic etch can be a plasma-based dry etch process and can use at least one of (C₄F₆) or (CF₄). The plasma-based dry etching process can use one or more of carbon monoxide (CO), oxygen (O₂), argon (Ar), or nitrogen (N₂) to remove etch byproducts. In some embodiments, second ILD layer 118B, second ESL 116B, first dielectric layer 118A, and first ESL 116A can be etched by a dry etching process using one or more of fluoromethane (CH₃F), difluoromethane (CH₂F₂), or octafluorocyclobutane (C₄F₈). In some embodiments, the plasma-based dry etching process can use a power between about 50 watts and about 1000 watts and a radio frequency (RF) between about 400 kHz and about 60 MHz. In some embodiments, the plasma-based dry etching process can be performed at a temperature between about −150 °C to about 200 °C. The plasma-based dry etching process is selective to the S/D regions. In other words, the plasma-based dry etching process does not etch the S/D regions 130A and 130B.

As shown in FIG. 9C, formation of opening 906 results in formation of isolation structure 132 on either side of opening 906. Isolation structure 132 can be formed of second ILD layer 118B, second ESL 116B, and first ILD layer 118A. In some embodiments, isolation structure 132 can have a tapered profile, as shown in the inset in FIG. 9C. Isolation structure 132 can be tapered at an angle θ, as shown in FIG. 9C. In some embodiments, θ can be between about 84° and about 89° with respect to the y-axis. In some embodiments, θ can be about 86.4°. Isolation structure 132 can have a top portion with width Wt3 and a bottom portion with width Wb3. In some embodiments, Wt3 can be between about 9 nm and about 193 nm, and Wb3 can be between about 10 nm and about 200 nm. In some embodiments, ratio of Wt3 and Wb3 can be between about 0.9 and about 0.97. After forming CMD opening 902, WC layer 302 can be removed. In some embodiments, a wet etching process using diluted hydrogen peroxide with hydrogent peroxide (H₂O₂) and H₂O in the ratio between about 1:20 and about 1:5, can be used to remove WC layer 302. In some embodiments, the wet etching can be performed at temperature of about 67 °C. In some embodiments, WC layer can be wet etched using hydrochloric acid (HCl), H₂O₂, and H₂O.

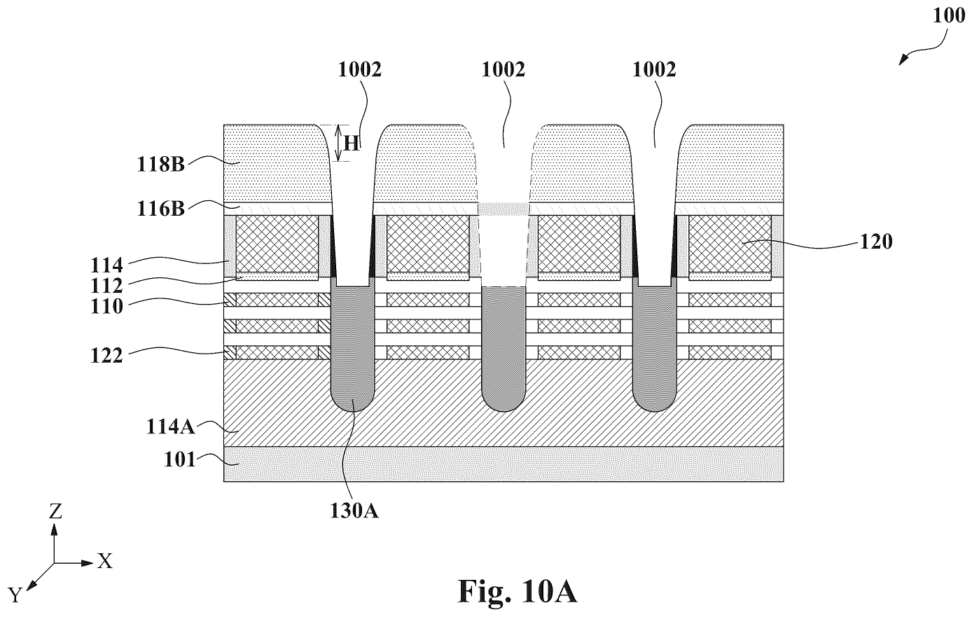

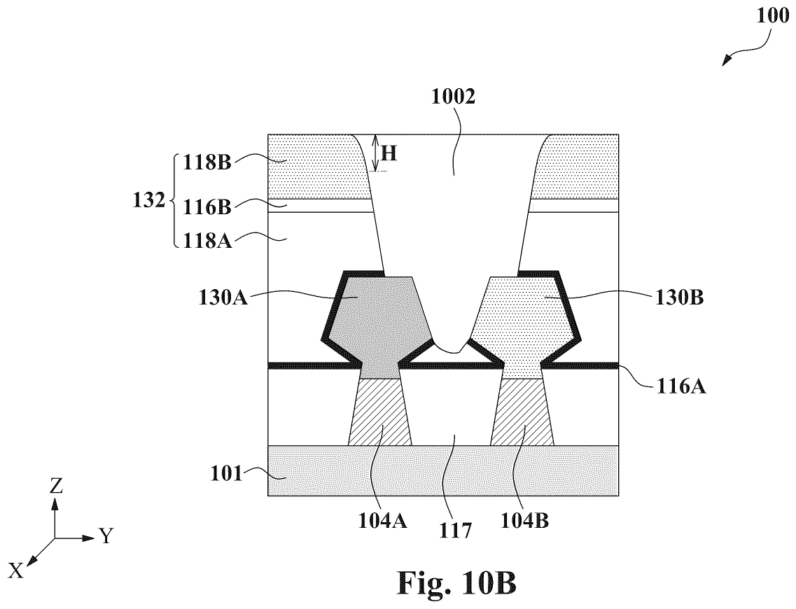

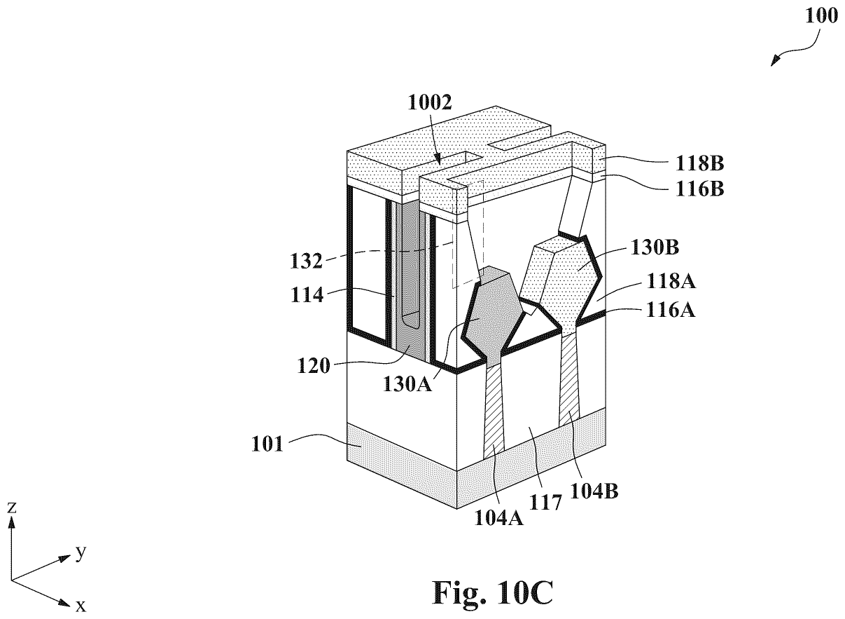

Referring to FIG. 2, in operation 230, top corners of second ILD layer are rounded to accommodate a larger volume of metal in S/D contact structures. As shown in FIGS. 10A, 10B, and 10C, top corners of second ILD layer 118B can be rounded to form CMD opening 1002. As illustrated in FIGS. 10A and 10B, rounded corners can be formed in a region at a depth H from a top surface of second ILD layer 118B. In some embodiments, depth H can be between about 1 nm and about 3 nm.

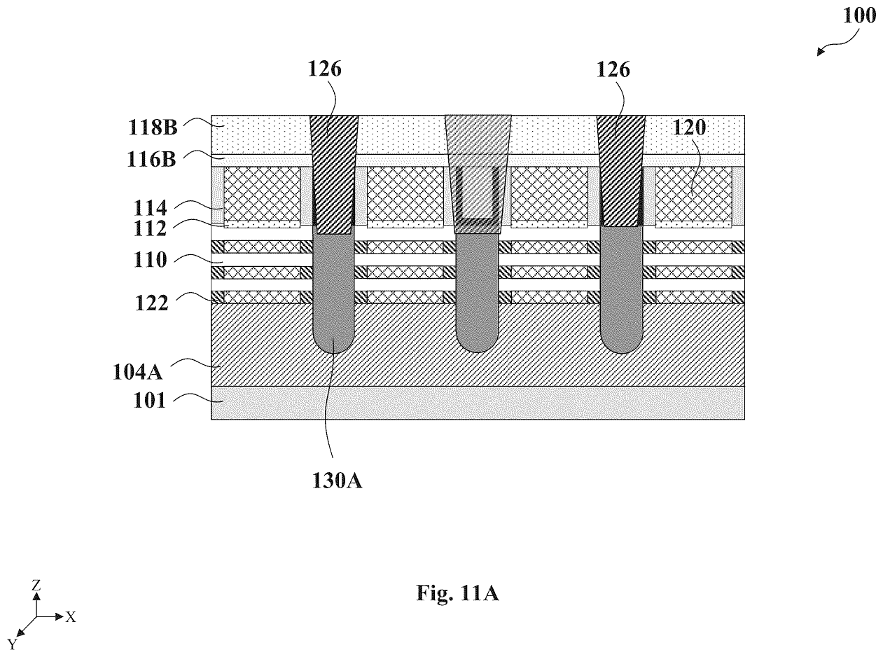

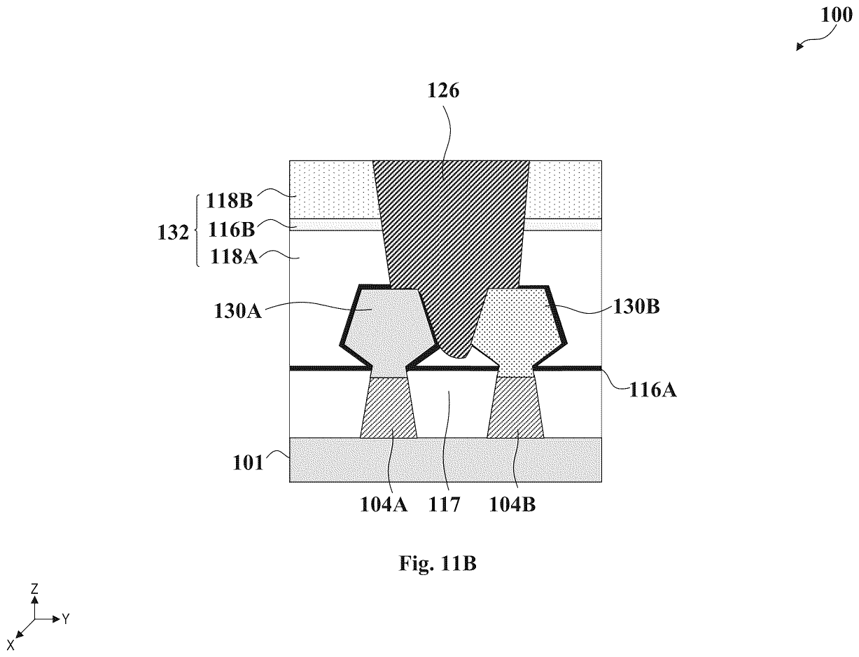

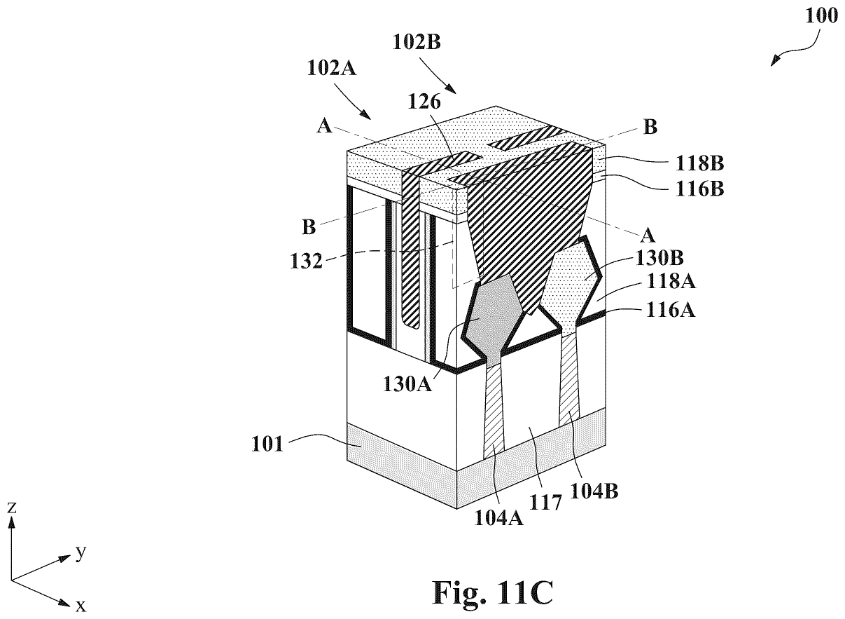

Referring to FIG. 2, in operation 235, contact structures are formed within the CMD opening. For example, as described with reference to FIGS. 11A, 11B, and 11C, S/D contact structures 126 are formed on S/D regions 130A and 130B. Subsequently, a top surface of S/D contact structure 126 is substantially co-planarized with a top surface of the second ILD layer. The formation of S/D contact structures 126 can include sequential operations of (i) forming a silicide layer (not shown) within CMD opening 1002, (ii) depositing a liner layer within CMD opening 1002 (not shown) (iii) depositing a metal layer on the silicide layer and liner layer to fill opening 1002 to form S/D contact structure 126, and (iv) performing a chemical mechanical polishing (CMP) process to substantially coplanarize a top surface of contact structure 126 with a top surface of second ILD layer 118B, to form the structures shown in FIGS. 11A and 11C. Isolation structure 132 can isolate contact structure 126 from another similar S/D contact structure formed on a neighboring fin structure.

The present disclosure provides method 200 for reducing a width of the isolation structure 132 between adjacent S/D contact structures 126. Isolation structure 132 with a small width can provide a large metal fill volume for S/D contact structures 126. The disclosed method can also form contact openings 902 with substantially vertical sidewalls which can also provide a large metal fill volume for S/D contact structures 126. The disclosure provides an improved method of forming CMD openings 1002. The disclosed method provides accurate alignment, etching and overall pattern fidelity for the CMD process and for forming other structures with other critical dimensions.

In some embodiments, a method can include providing a substrate comprising source/drain (S/D) regions formed on adjacent fin structures, where the S/D regions are surrounded by a first dielectric layer, depositing an etch stop layer on the first dielectric layer, depositing a second dielectric layer on the etch stop layer, depositing a tungsten carbide (WC) layer on the second dielectric layer, depositing a capping layer on the WC layer, and depositing a silicon layer on the capping layer. The method can further include etching the capping layer and the WC layer to form a first opening, performing ion implantation on sidewalls of the capping layer and the WC layer to form an implanted portion on sidewalls of the capping layer and the WC layer, etching the implanted portion through the first opening to form a second opening, etching the second dielectric layer, the etch stop layer, and the first dielectric layer through the second opening to form a S/D contact opening, and filling the S/D contact opening with a metal layer.

In some embodiments, a method can include providing a GAA FET with a first dielectric layer, forming an etch stop layer and a second dielectric layer on the first dielectric layer, depositing a tungsten carbide (WC) layer on the second dielectric layer, and depositing an oxide layer on the WC layer. The method can further include etching the WC layer and the oxide layer to form a first opening, ion implanting sidewalls of the WC layer and the oxide layer to form an implanted region, etching the implanted region to form a second opening larger than the first opening, etching the second dielectric layer, the etch stop layer, the first dielectric layer, and a portion of a source/drain (S/D) region of the GAA FET to form a trench, and filling the trench with a contact layer.

In some embodiments, a structure can include a first GAA FET comprising a first channel region and a first source/drain (S/D) region, a second GAA FET comprising a second channel region and a second source/drain region, and an isolation structure disposed between a first contact structure of the first S/D region and a second contact structure of the second S/D region, where a vertical sidewall of the isolation structure is at an angle greater than about 85° relative to a horizontal direction.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a substrate comprising source/drain (S/D) regions formed on adjacent fin structures, wherein the S/D regions are surrounded by a first dielectric layer;
depositing an etch stop layer on the first dielectric layer;
depositing a second dielectric layer on the etch stop layer;
depositing a metal-based layer on the second dielectric layer;
depositing a capping layer on the metal-based layer;
depositing a silicon layer on the capping layer;
etching the capping layer and the metal-based layer to form a first opening;
performing ion implantation on sidewalls of the capping layer and the metal-based layer to form an implanted portion on sidewalls of the capping layer and the metal-based layer;
etching the implanted portion through the first opening to form a second opening;
etching the second dielectric layer, the etch stop layer, and the first dielectric layer through the second opening to form a S/D contact opening; and
filling the S/D contact opening with a metal layer.

2. The method of claim 1, wherein performing the ion implantation comprises directing ions on the sidewalls of the capping layer and the metal-based layer at an angle between about 2° and about 88°.

3. The method of claim 1, further comprising etching the implanted portion with diluted hydrogen fluoride and diluted ammonium hydroxide.

4. The method of claim 1, further comprising ion implanting the sidewalls of the capping layer and the metal-based layer with at least one of argon ions, xenon ions, or oxygen ions.

5. The method of claim 1, further comprising performing the ion implantation at a temperature between about 150 °C and about 600 °C.

6. The method of claim 1, further comprising etching the implanted portion using diluted ammonium hydroxide at a temperature between about 20 °C and about 70 °C.

7. The method of claim 1, further comprising etching the implanted portion with diluted ammonium hydroxide between about 55 seconds and about 65 seconds.

8. A method comprising:
providing a GAA FET with a first dielectric layer;
forming an etch stop layer and a second dielectric layer on the first dielectric layer;
depositing a metal-based layer on the second dielectric layer;
depositing an oxide layer on the metal-based layer;
etching the metal-based layer and the oxide layer to form a first opening;
ion implanting sidewalls of the metal-based layer and the oxide layer with inert ions to form an implanted region;
etching the implanted region to form a second opening larger than the first opening;
etching the second dielectric layer, the etch stop layer, the first dielectric layer, and a portion of a source/drain (S/D) region of the GAA FET to form a trench; and
filling the trench with a contact layer.

9. The method of claim 8, further comprising:
forming a stack of patterning layers on the oxide layer, wherein forming the stack of patterning layers comprises:
depositing a silicon layer on the oxide layer;
forming a first patterning layer on the silicon layer;
forming a second patterning layer on the first patterning layer; and
patterning and etching the first patterning layer, the second patterning layer, and the silicon layer to form a first patterned mask structure.

10. The method of claim 9, further comprising:
depositing the first patterning layer and the second patterning layer over the first patterned mask structure; and
patterning and etching the first patterning layer, the second patterning layer, the oxide layer, the metal-based layer, and a portion of the second dielectric layer to form a second patterned mask structure.

11. The method of claim 10, further comprising etching the second dielectric layer, the etch stop layer, the first dielectric layer, and a portion of the S/D region through the first and second patterned mask structures to form a contact opening.

12. The method of claim 11, further comprising performing an etching process to round-off top corners of the second dielectric layer.

13. The method of claim 12, further comprising chemical mechanical polishing the contact layer and the second dielectric layer to substantially co-planarize a top surface of the contact layer with a top surface of the second dielectric layer.

14. The method of claim 8, wherein ion implanting sidewalls of the metal-based layer comprises implanting the sidewalls of the metal-based layer and the oxide layer with xenon ions.

15. The method of claim 8, further comprising increasing a thickness of the implanted region by increasing a concentration of xenon ions.

16. The method of claim 8, further comprising oxidizing the metal-based layer after the implanting.

17. The method of claim 8, further comprising etching the implanted region with diluted hydrogen fluoride and diluted ammonium hydroxide.

18. A structure, comprising:
a first GAA FET comprising a first channel region and a first source/drain (S/D) region;
a second GAA FET comprising a second channel region and a second source/drain region; and
an isolation structure disposed between a first contact structure of the first S/D region and a second contact structure of the second S/D region, wherein a vertical sidewall of the isolation structure is at an angle equal to or greater than about 84° relative to a horizontal direction.

19. The structure of claim 18, wherein top surfaces of the first contact layer and the second contact layer are substantially co-planar with a top surface of the isolation structure.

20. The structure of claim 18, wherein the isolation structure comprises:
a first dielectric layer;
an etch stop layer disposed on the first dielectric layer; and
a second dielectric layer disposed on the etch stop layer.
